(19) United States
(12) Patent Application Publication
(10) Pub. No.: US 2026/0173852 A1
(43) Pub. Date: Jun. 18, 2026

(54) SEMICONDUCTOR DEVICE

(71) Applicant: Kioxia Corporation, Tokyo (JP)

(72) Inventor: Ryuji KUBO, Kuwana Mie (JP)

(73) Assignee: Kioxia Corporation, Tokyo (JP)

(21) Appl. No.: 19/311,980

(22) Filed: Aug. 27, 2025

(30) Foreign Application Priority Data
Dec. 18, 2024 (JP) 2024-221799

(51) Int. Cl. H01L 23/528; H01L 21/768; H01L 23/522

(52) U.S. Cl. CPC H10W 20/435; H10W 20/42; H10W 20/43; H10W 20/056; H10W 20/084

(57) ABSTRACT

A semiconductor device includes a first wiring and a second wiring adjacent to each other in a first direction. The first wiring includes a first extending portion extending in a second direction, and a first plug portion extending in a third direction and in contact with the first extending portion on a first side in the third direction. The second wiring includes a second extending portion provided in a same layer as the first extending portion and extending in the second direction, and a first connection portion adjacent to the first plug portion in the first direction and in contact with the second extending portion in the second direction. A position of a surface of the first connection portion on the second side is different from a position of a surface of the second extending portion on the second side in the third direction.

### CROSS-REFERENCE TO RELATED APPLICATION

This application is based upon and claims the benefit of priority from Japanese Patent Application No. 2024-221799, filed Dec. 18, 2024, the entire contents of which are incorporated herein by reference.

### FIELD

Embodiments described herein relate generally to a semiconductor device.

### BACKGROUND

Semiconductor devices including a wiring formed using techniques such as a single damascene technique and a dual damascene technique are known.

### DESCRIPTION OF THE DRAWINGS

FIG. 1 is a cross-sectional view showing an example of a portion of a semiconductor device according to a first embodiment.

FIG. 2 is a cross-sectional view showing an example of a portion of the semiconductor device according to the first embodiment.

FIG. 3 is a cross-sectional view taken along line III-III in FIG. 2, showing an example of a portion of the semiconductor device according to the first embodiment.

FIG. 4 is a cross-sectional view taken along line IV-IV in FIG. 2, showing an example of a portion of the semiconductor device according to the first embodiment.

FIG. 5 is a cross-sectional view showing an example of a manufacturing method of the semiconductor device according to the first embodiment.

FIG. 6 is a top view showing an example of the manufacturing method of the semiconductor device according to the first embodiment.

FIG. 7 is a cross-sectional view showing an example of the manufacturing method of the semiconductor device according to the first embodiment.

FIG. 8 is a cross-sectional view showing an example of the manufacturing method of the semiconductor device according to the first embodiment.

FIG. 9 is a cross-sectional view showing an example of the manufacturing method of the semiconductor device according to the first embodiment.

FIG. 10 is a cross-sectional view showing an example of the manufacturing method of the semiconductor device according to the first embodiment.

FIG. 11 is a top view showing an example of the manufacturing method of the semiconductor device according to the first embodiment.

FIG. 12 is a cross-sectional view showing an example of the manufacturing method of the semiconductor device according to the first embodiment.

FIG. 13 is a cross-sectional view showing an example of the manufacturing method of the semiconductor device according to the first embodiment.

FIG. 14 is a cross-sectional view showing an example of the manufacturing method of the semiconductor device according to the first embodiment.

FIG. 15 is a cross-sectional view showing an example of a portion of a semiconductor device according to a first modification example of the first embodiment.

FIG. 16 is a cross-sectional view showing an example of a manufacturing method of the semiconductor device according to the first modification example of the first embodiment.

FIG. 17 is a cross-sectional view showing an example of a portion of a semiconductor device according to a second modification example of the first embodiment.

FIG. 18 is a cross-sectional view showing an example of a portion of a semiconductor device according to a third modification example of the first embodiment.

FIG. 19 is a cross-sectional view showing an example of a portion of the semiconductor device according to the third modification example of the first embodiment.

FIG. 20 is a cross-sectional view showing an example of a manufacturing method of the semiconductor device according to the third modification example of the first embodiment.

FIG. 21 is a cross-sectional view showing an example of the manufacturing method of the semiconductor device according to the third modification example of the first embodiment.

FIG. 22 is a cross-sectional view showing an example of a portion of a semiconductor device according to a fourth modification example of the first embodiment.

FIG. 23 is a cross-sectional view showing an example of a manufacturing method of the semiconductor device according to the fourth modification example of the first embodiment.

FIG. 24 is a cross-sectional view showing an example of the manufacturing method of the semiconductor device according to the fourth modification example of the first embodiment.

FIG. 25 is a cross-sectional view showing an example of a portion of a semiconductor device according to a fifth modification example of the first embodiment.

FIG. 26 is a cross-sectional view showing an example of a portion of the semiconductor device according to the fifth modification example of the first embodiment.

FIG. 27 is a cross-sectional view showing an example of a manufacturing method of the semiconductor device according to the fifth modification example of the first embodiment.

FIG. 28 is a cross-sectional view showing an example of a portion of a semiconductor device according to a sixth modification example of the first embodiment.

FIG. 29 is a cross-sectional view showing an example of a portion of a semiconductor device according to a second embodiment.

FIG. 30 is a cross-sectional view showing an example of a portion of the semiconductor device according to the second embodiment.

FIG. 31 is a cross-sectional view taken along line XXXI-XXXI in FIG. 30, showing an example of a portion of the semiconductor device according to the second embodiment.

FIG. 32 is a cross-sectional view taken along line XXXII-XXXII in FIG. 30, showing an example of a portion of the semiconductor device according to the second embodiment.

FIG. 33 is a cross-sectional view showing an example of a manufacturing method of the semiconductor device according to the second embodiment.

FIG. 34 is a top view showing an example of the manufacturing method of the semiconductor device according to the second embodiment.

FIG. 35 is a cross-sectional view showing an example of the manufacturing method of the semiconductor device according to the second embodiment.

FIG. 36 is a cross-sectional view showing an example of the method manufacturing of the semiconductor device according to the second embodiment.

FIG. 37 is a cross-sectional view showing an example of the manufacturing method of the semiconductor device according to the second embodiment.

### DETAILED DESCRIPTION

In general, according to one embodiment, a semiconductor device includes a first wiring and a second wiring adjacent to each other in a first direction along a first face, the first wiring includes a first extending portion extending in a second direction intersecting the first direction along the first face, and a first plug portion extending in a third direction intersecting the first face and being in contact with the first extending portion on a first side in the third direction, the second wiring includes a second extending portion provided in a same layer as the first extending portion and extending in the second direction, and a first connection portion adjacent to the first plug portion in the first direction and being in contact with the second extending portion side by side in the second direction, and a first position of a surface of the first connection portion on a second side that is opposite to the first side in the third direction is different from a second position of a surface of the second extending portion on the second side in the third direction.

Hereinafter, embodiments will be described with reference to the drawings. The dimensions and ratios of the drawings are not necessarily the same as those in reality. In the following description, components having substantially the same functions and configurations are given the same reference numerals.

In addition, when elements having similar configurations are to be particularly distinguished from each other, different letters or numbers may be added to the ends of the same reference numerals.

### 1. First Embodiment

Hereinafter, a semiconductor device according to a first embodiment will be described.

In the following description, an X-direction is a direction substantially parallel to a substrate of the semiconductor device. A Y-direction is a direction substantially parallel to the substrate and orthogonal to the X-direction. The Z-direction is a direction substantially perpendicular to the substrate.

### 1.1 Configuration

The configuration of the semiconductor device according to the first embodiment will be described. Hereinafter, the configuration of parts provided in the semiconductor device will be described.

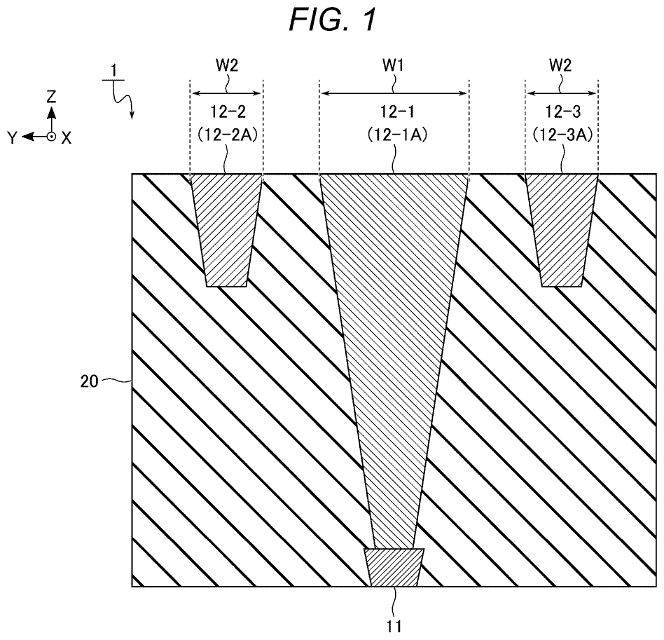

FIG. 1 is a cross-sectional view showing an example of a portion of the semiconductor device according to the first embodiment. In FIG. 1, the configuration of a portion of a semiconductor device 1 in a YZ cross-section is shown.

The semiconductor device 1 includes conductor layers 11, 12-1, 12-2, and 12-3, and an insulator layer 20. The conductor layers 11, 12-1, 12-2, and 12-3 function as wirings that are electrically connected to a circuit provided on a substrate (not shown), for example.

The conductor layer 11 is provided, for example, above the substrate (not shown). The conductor layer 11 is electrically connected to a circuit provided on the substrate.

The conductor layer 12-1 is provided on the upper surface of the conductor layer 11. As will be described later, the conductor layer 12-1 includes portions 12-1A, 12-1B, and 12-1C. As shown in FIG. 1, the conductor layer 12-1 is provided such that the lower surface of the portion 12-1A is in contact with the upper surface of the conductor layer 11. The portion 12-1A extends in the Z-direction. The portion 12-1A has a width W1 in the Y-direction at its upper end. The portion 12-1A functions as a via or plug electrically connected to the conductor layer 11.

The conductor layers 12-2 and 12-3 are provided, for example, adjacent to the conductor layer 12-1 in the Y-direction. The conductor layers 12-2 and 12-3 are provided to sandwich the conductor layer 12-1 in the Y-direction. As will be described below, the conductor layer 12-2 includes portions 12-2A, 12-2B, and 12-2C. The conductor layer 12-3 includes portions 12-3A, 12-3B, and 12-3C. In the cross-section shown in FIG. 1, the portions 12-2A and 12-3A are included. A width W2 in the Y-direction at the upper ends of the portions 12-2A and 12-3A is smaller than the width W1 of the portion 12-1A (W1>W2). In the Z-direction, the lower surfaces of the portions 12-2A and 12-3A are located, for example, above the lower surface of the portion 12-1A.

The conductor layers 11, 12-1, 12-2, and 12-3 are provided in the insulator layer 20. The upper surface of the conductor layer 12-1, the upper surface of the conductor layer 12-2, and the upper surface of the conductor layer 12-3 are provided to be flush with the upper surface of the insulator layer 20, for example.

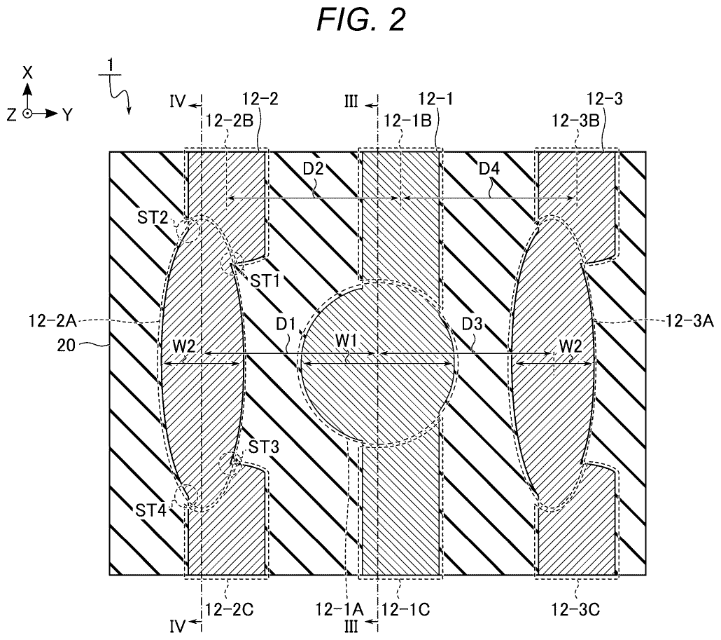

The configuration of the semiconductor device 1 in an XY cross-section including the upper surfaces of the conductor layers 12-1, 12-2, and 12-3 will be described with reference to FIG. 2. FIG. 2 is a cross-sectional view showing an example of a portion of the semiconductor device according to the first embodiment. FIG. 2 shows the configuration of a portion of the semiconductor device 1 in the XY cross-section at a position equivalent to the upper surfaces of the conductor layers 12-1 to 12-3.

In the conductor layer 12-1, the portions 12-1B, 12-1A, and 12-1C are arranged in this order in the X-direction. The portions 12-1B and 12-1C each extend in the X-direction. The portions 12-1B and 12-1C are, for example, provided on substantially the same straight line. The portion 12-1A has, for example, a substantially circular shape when viewed from above. The portion 12-1A is in contact with the portion 12-1B on one side in the X-direction. The portion 12-1A is in contact with the portion 12-1C on the other side in the X-direction. In addition, the width W1 of the portion 12-1A is, for example, wider than the width of the portion 12-1B in the Y-direction and the width of the portion 12-1C in the Y-direction.

In the conductor layer 12-2, the portions 12-2B, 12-2A, and 12-2C are arranged in this order in the X-direction. The portions 12-2B and 12-2C each extend in the X-direction. The portions 12-2B and 12-2C are, for example, provided on substantially the same straight line. The portion 12-2A has, for example, a substantially elliptical shape with the X-direction as the major axis direction when viewed from above. The portion 12-2A is in contact with the portion 12-2B on one side in the X-direction. The portion 12-2A is in contact with the portion 12-2C on the other side in the X-direction. When viewed from above, the conductor layer 12-2 has, for example, a stepped shape at a point where the portions 12-2A and 12-2B are connected, due to the shapes of these portions. In addition, when viewed from above, the conductor layer 12-2 has a stepped shape at a point where the portions 12-2A and 12-2C are connected, due to the shapes of these portions. FIG. 2 shows steps ST1 and ST2 on one side and the other side in the Y-direction at a point where the portions 12-2A and 12-2B are connected, and steps ST3 and ST4 on one side and the other side in the Y-direction at a point where the portions 12-2A and 12-2C are connected.

In the conductor layer 12-3, the portions 12-3B, 12-3A, and 12-3C are arranged in this order in the X-direction. The portions 12-3A, 12-3B, and 12-3C correspond to the portions 12-2A, 12-2B, and 12-2C, respectively. The structure of the conductor layer 12-3 is substantially the same as the structure of the conductor layer 12-2.

In the above-described configuration, the portions 12-1A and 12-2A, and the portions 12-1A and 12-3A are arranged adjacent to each other in the Y-direction. Furthermore, the portions 12-2A and 12-3A are arranged to overlap the portion 12-1A in the Y-direction.

The center of the portion 12-1A in the Y-direction and the centers of the portions 12-1B and 12-1C in the Y-direction may be shifted in the Y-direction, or may be aligned in the Y-direction. FIG. 2 shows an example of a case where the center of the portion 12-1A in the Y-direction is shifted in the Y-direction with respect to the centers of the portions 12-1B and 12-1C in the Y-direction. When viewed from above, an arrangement relationship between the portions 12-2A, 12-2B, and 12-2C and an arrangement relationship between the portions 12-3A, 12-3B, and 12-3C are similar to, for example, an arrangement relationship between the portions 12-1A, 12-1B, and 12-1C. That is, when the center of the portion 12-1A in the Y-direction is shifted to one side or the other side in the Y-direction with respect to the centers of the portions 12-1B and 12-1C in the Y-direction, the center of the portion 12-2A in the Y-direction is shifted to one side or the other side in the Y-direction with respect to the centers of the portions 12-2B and 12-2C in the Y-direction. In this case, the center of the portion 12-3A in the Y-direction is shifted to one side or the other side in the Y-direction with respect to the centers of the portions 12-3B and 12-3C in the Y-direction. When the center of the portion 12-1A in the Y-direction is aligned with the centers of the portions 12-1B and 12-1C in the Y-direction, the center of the portion 12-2A in the Y-direction is aligned with the centers of the portions 12-2B and 12-2C in the Y-direction. In this case, the center of the portion 12-3A in the Y-direction is aligned with the centers of the portions 12-3B and 12-3C in the Y-direction.

In addition, a distance D1 between the center of the portion 12-1A in the Y-direction and the center of the portion 12-2A in the Y-direction is, for example, substantially equal to a distance D2 between the centers of the portions 12-1B and 12-1C in the Y-direction and the centers of the portions 12-2B and 12-2C in the Y-direction. In addition, a distance D3 between the center of the portion 12-1A in the Y-direction and the center of the portion 12-3A in the Y-direction is substantially equal to a distance D4 between the centers of the portions 12-1B and 12-1C in the Y-direction and the centers of the portions 12-3B and 12-3C in the Y-direction.

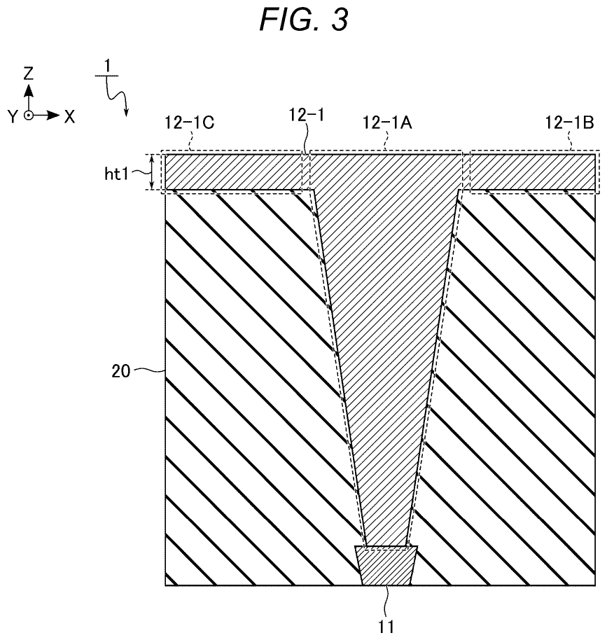

The configuration of the semiconductor device 1 in the XZ cross-section including the conductor layer 12-1 will be described with reference to FIG. 3. FIG. 3 is a cross-sectional view taken along line III-III in FIG. 2, showing an example of a portion of the semiconductor device according to the first embodiment.

The upper surface of the portion 12-1B and the upper surface of the portion 12-1C are provided to be flush with the upper surface of the portion 12-1A. The lower surface of the portion 12-1B and the lower surface of the portion 12-1C are located above the lower surface of the portion 12-1A. The portions 12-1B and 12-1C have approximately a height ht1 in the Z-direction.

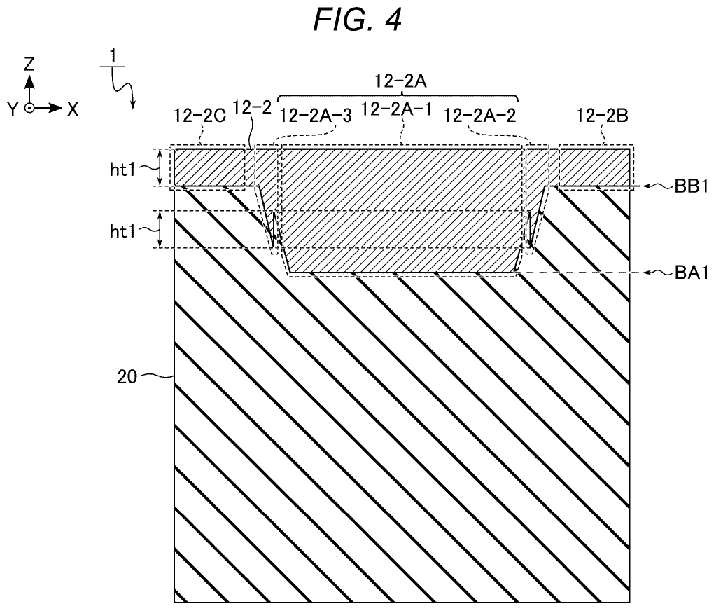

The configuration of the semiconductor device 1 in the XZ cross-section including the conductor layer 12-2 will be described with reference to FIG. 4. FIG. 4 is a cross-section taken along line IV-IV in FIG. 2, showing an example of a portion of the semiconductor device according to the first embodiment.

The upper surface of the portion 12-2A, the upper surface of the portion 12-2B, and the upper surface of the portion 12-2C are provided to be flush with each other. The portion 12-2A includes sub-portions 12-2A-1, 12-2A-2, and 12-2A-3. The sub-portion 12-2A-2 and 12-2A-3 sandwich the sub-portion 12-2A-1 in the X-direction. The sub-portion 12-2A-2 is sandwiched by the sub-portion 12-2A-1 and the portion 12-2B in the X-direction. The sub-portion 12-2A-2 is also in contact with the sub-portion 12-2A-1 and the portion 12-2B. The sub-portion 12-2A-3 is sandwiched by the sub-portion 12-2A-1 and the portion 12-2C in the X-direction. The sub-portion 12-2A-3 is also in contact with the sub-portion 12-2A-1 and the portion 12-2C.

The sub-portion 12-2A-1 has a lower surface that is substantially parallel to the substrate. The position of the lower surface in the Z-direction is a position BA1. The position BA1 is, for example, below a position BB1 in the Z-direction of the lower surfaces of the portions 12-2B and 12-2C. The portions 12-2B and 12-2C have approximately a height ht1 in the Z-direction, similar to the portions 12-1B and 12-1C.

The portion 12-2A has a stepped shape in the XZ cross-section at a point where the sub-portions 12-2A-1 and 12-2A-2 are connected and at a point where the sub-portions 12-2A-1 and 12-2A-3 are connected, for example, due to a manufacturing process to be described later. The sub-portion 12-2A-2 configures, for example, a protruding portion that protrudes downward from the position BB1 between the sub-portion 12-2A-1 and the portion 12-2B. The height in the Z-direction between the position of a lower end at a boundary where the sub-portion 12-2A-2 is in contact with the sub-portion 12-2A-1 and the position of a lower end of the sub-portion 12-2A-2 is, for example, approximately a height ht1. In addition, the sub-portion 12-2A-3 constitutes, for example, a protruding portion that protrudes downward from the position BB1 between the sub-portion 12-2A-1 and the portion 12-2C. The height in the Z-direction between the position of the lower end at the boundary where the sub-portion 12-2A-3 is in contact with the sub-portion 12-2A-1 and the position of the lower end of the sub-portion 12-2A-3 is, for example, approximately a height ht1.

Although not shown in the drawing, the structure of the conductor layer 12-3 in the XZ cross-section is substantially the same as the structure of the conductor layer 12-2 shown in FIG. 4.

### 1.2 Manufacturing Method

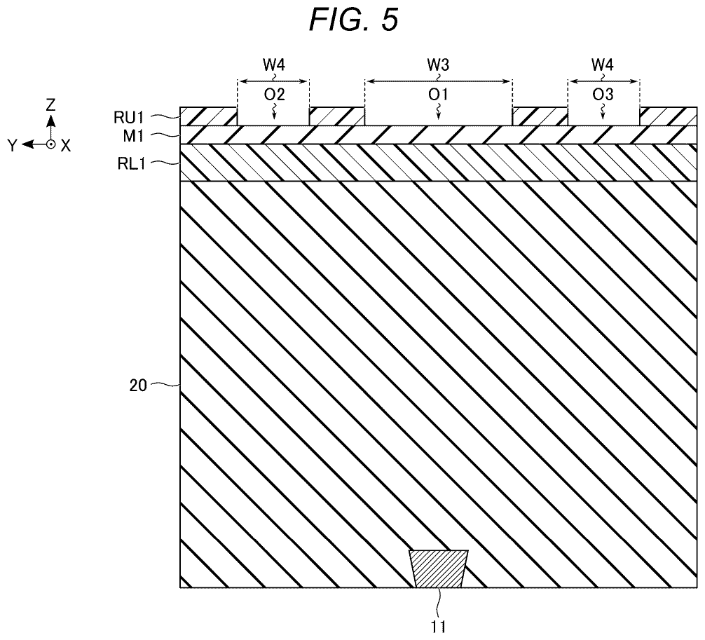

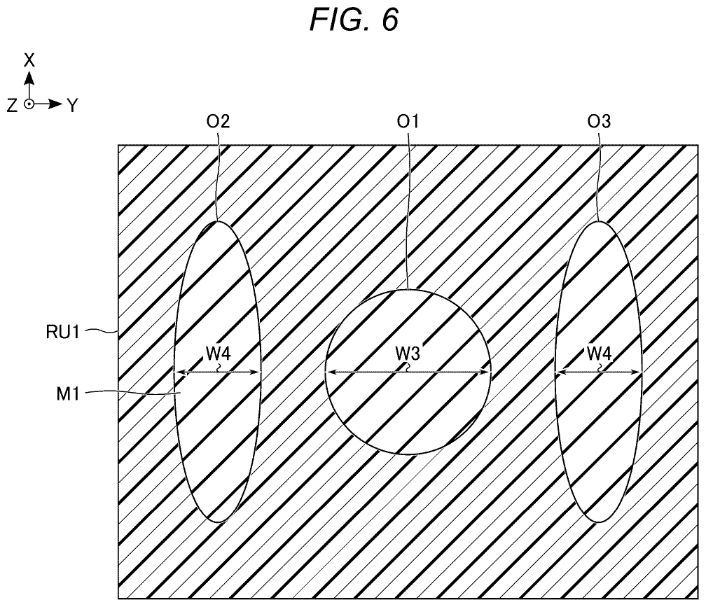

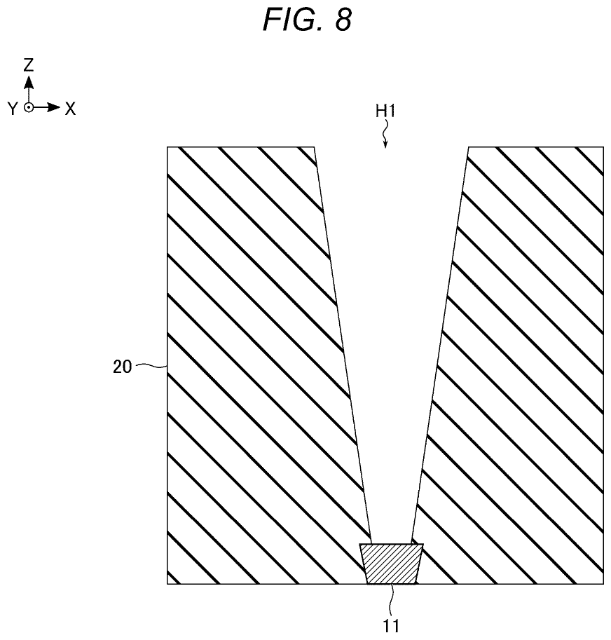

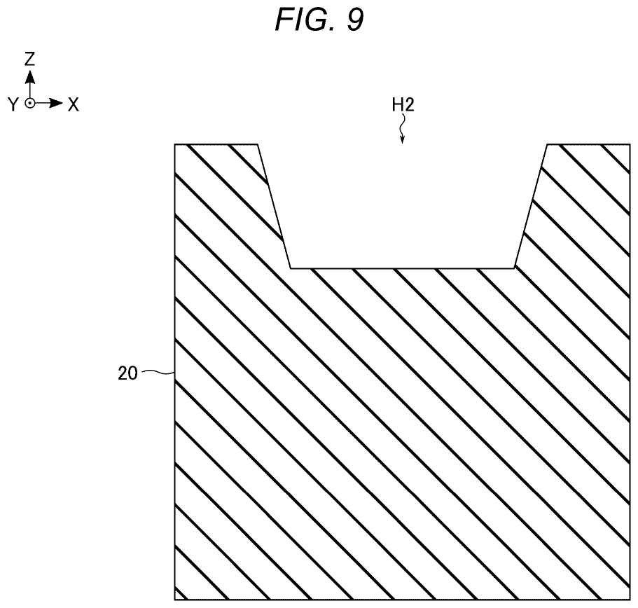

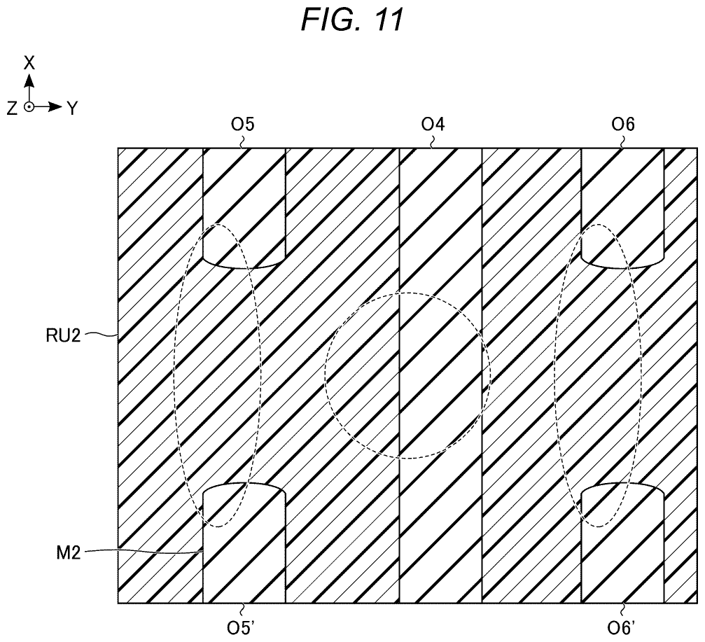

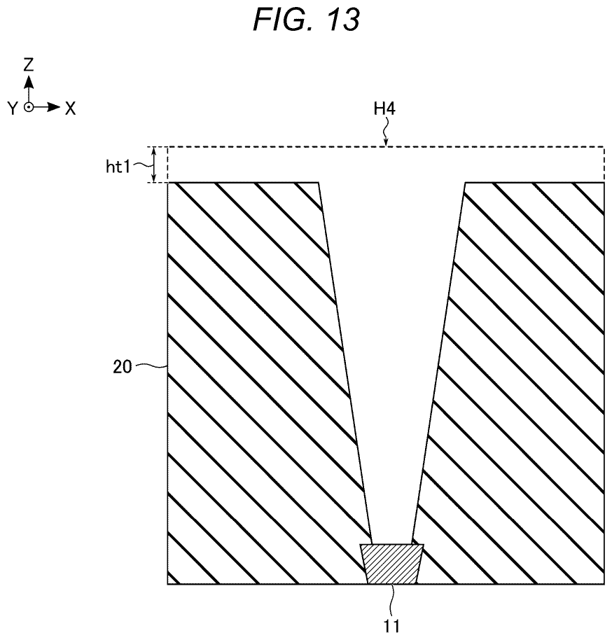

A manufacturing method of the semiconductor device 1 will be described with reference to FIGS. 5 to 14. FIGS. 5, 7 to 10, and 12 to 14 are cross-sectional views showing an example of the manufacturing method of the semiconductor device according to the first embodiment. FIGS. 6 and 11 are top views showing an example of the manufacturing method of the semiconductor device according to the first embodiment. The cross-sectional views shown in FIGS. 5, 7, and 10 show the region corresponding to FIG. 1. The views shown in FIGS. 6 and 11 are top views of the region corresponding to FIG. 2 as viewed from above. The cross-sectional views shown in FIGS. 8 and 13 show the region corresponding to FIG. 3. The cross-sectional views shown in FIGS. 9, 12, and 14 show the region corresponding to FIG. 4.

First, the conductor layer 11 and the insulator layer 20 are formed above the substrate. Then, as shown in FIGS. 5 and 6, for example, a resist RL1, an intermediate layer M1, and a resist RU1 are stacked in this order on the upper surface of the insulator layer 20. The resist RU1 has openings O1, O2, and O3. The openings O1, O2, and O3 are formed in portions where the portions 12-1A, 12-2A, and 12-3A are to be formed, respectively. A width W3 of the opening O1 in the Y-direction is greater than a width W4 of each of the openings O2 and O3 in the Y-direction. The widths W3 and W4 are, for example, substantially equal to the widths W1 and W2, respectively.

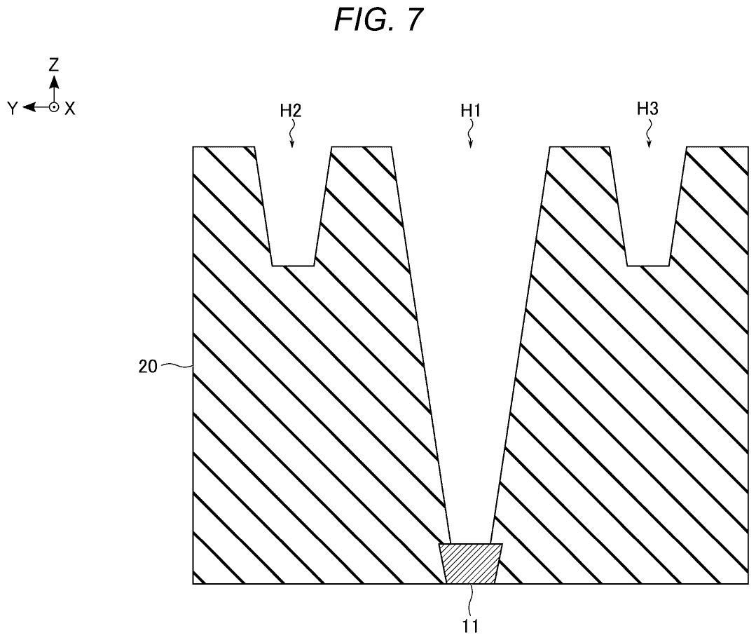

Next, portions of the insulator layer 20 are removed together with the resist RL1 and the intermediate layer M1 in the openings O1, O2, and O3 by etching using the resist RL1, the intermediate layer M1, and the resist RU1 formed as described above. After the etching, the resist RL1, the intermediate layer M1, and the resist RU1 are also removed. Through the above processing, holes H1, H2, and H3 are formed as shown in FIGS. 7, 8, and 9. The holes H1, H2, and H3 correspond to the portions where the portions 12-1A, 12-2A, and 12-3A are to be formed, respectively. As shown in FIGS. 7 and 8, the upper surface of the conductor layer 11 is exposed at the bottom surface of the hole H1. As described above, the width W4 of the openings O2 and O3 is smaller than the width W3 of the opening O1. Thereby, in the above etching, an etching speed at the openings O2 and O3 is slower than an etching speed at the opening O1 due to a microloading effect. For this reason, when the upper surface of the conductor layer 11 functioning as a stopper is exposed during etching and the hole H1 is formed, the bottom surfaces of the holes H2 and H3 are positioned above the bottom surface of the hole H1. Each of the holes H1, H2, and H3 has, for example, a tapered shape in which the width in the X-direction and the width in the Y-direction increase from the bottom to the top.

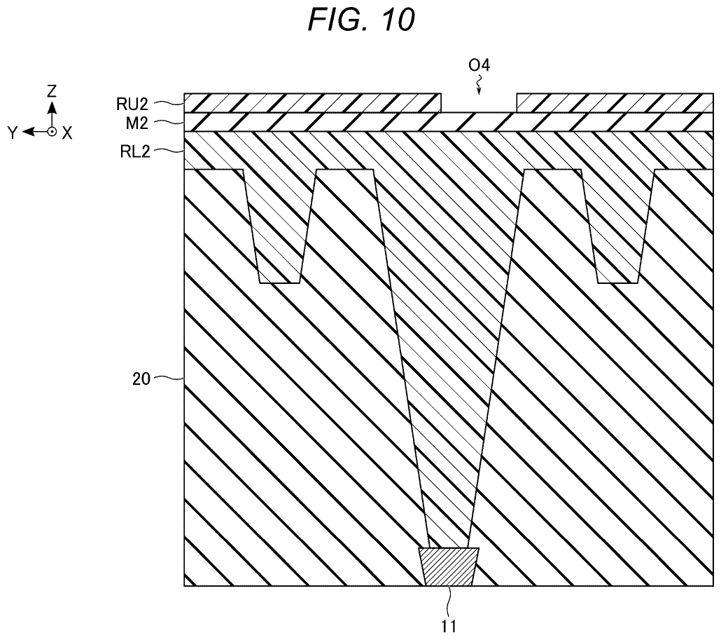

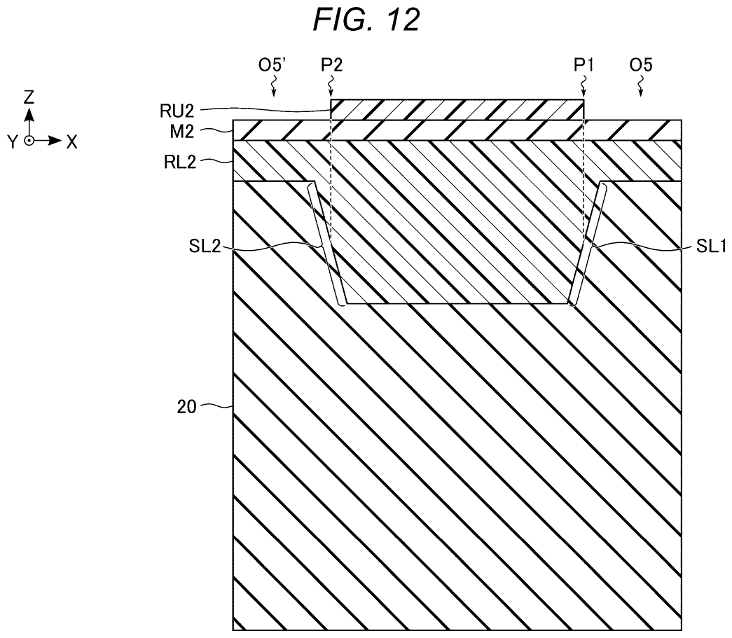

As shown in FIGS. 10, 11, and 12, for example, a resist RL2, an intermediate layer M2, and a resist RU2 are stacked in this order on the upper surface of the insulator layer 20 in which the holes H1, H2, and H3 are formed. In FIG. 11, the portions in which the portions 12-1A, 12-2A, and 12-3A are to be formed are shown by dotted lines. The resist RL2 is formed, for example, to be embedded in the holes H1, H2, and H3. The upper surface of the resist RL2 is formed, for example, to be flush above the insulator layer 20. The resist RU2 has openings O4, O5, O5′, O6, and O6′. The opening O4 is formed in the form of a straight line extending in the X-direction so as to overlap the portion where the portion 12-1A is to be formed as viewed from above and include the portions where the portions 12-1B and 12-1C are to be formed. The opening O4 is formed to cross, in the X-direction, the portion where the portion 12-1A is to be formed, as viewed from above. The openings O5 and O5′ are each formed in the form of a straight line extending in the X-direction so as to include the portions where the portions 12-2B and 12-2C are to be formed. As shown in FIG. 12, the opening O5 overlaps a part of the portion corresponding to one side surface of the hole H2 in the X-direction in the process described using FIGS. 7 to 9. The portion of the surface of the insulator layer 20 corresponding to one side surface of the hole H2 in the X-direction is referred to as a portion SL1. In the XZ cross-section, a position P1 on the other side of the opening O5 in the X-direction is located between the position on one side and the position on the other side of the portion SL1 in the X-direction. In addition, the opening O5′ overlaps a part of the portion corresponding to the other side surface of the hole H2 in the X-direction in the process described using FIGS. 7 to 9. The portion of the surface of the insulator layer 20 corresponding to the other side surface of the hole H2 in the X-direction is referred to as a portion SL2. In the XZ cross-section, a position P2 on one side of the opening O5 in the X-direction is located between a position on one side and a position on the other side of the portion SL2 in the X-direction. The openings O6 and O6′ are formed in the form of a straight line extending in the X-direction so as to include the portions where the portions 12-3B and 12-3C are to be formed. Although the XZ cross-section including the openings O6 and O6′ is not illustrated, the XZ cross-section including the openings O6 and O6′ is substantially equivalent to the XZ cross-section including the openings O5 and O5′ shown in FIG. 12.

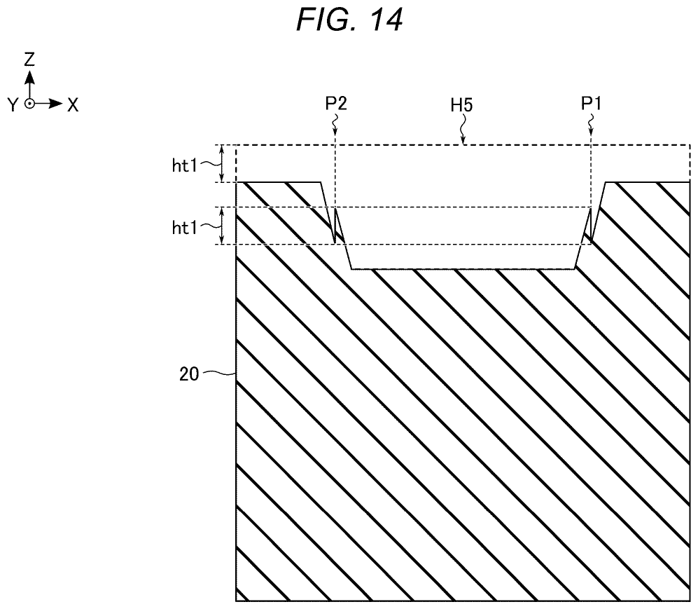

Then, the portions of the insulator layer 20 are removed together with the resist RL2 and the intermediate layer M2 in the openings O4, O5, O5′, O6, and O6′ by etching using the resist RL2, the intermediate layer M2, and the resist RU2 formed as described above. After the etching, the resist RL2, the intermediate layer M2, and the resist RU2 are also removed. Through the above processing, holes are formed corresponding to the portions where the conductor layers 12-1, 12-2, and 12-3 are to be formed, as shown in FIGS. 13 and 14. In FIGS. 13 and 14, the insulator layer 20 in the portions where the holes are not formed is shown by dotted lines. In a portion overlapping the opening O4 when viewed from above, the insulator layer 20 is removed by approximately a height ht1 through the above etching. Thereby, as shown in FIG. 13, a hole H4 corresponding to the portion where the conductor layer 12-1 is to be formed is formed. Further, in the portion overlapping the openings O5 and O5′ as viewed from above, the insulator layer 20 is removed by, for example, approximately the height ht1, as in the portion overlapping the opening O4 as viewed from above. Thereby, as shown in FIG. 14, a hole H5 corresponding to the portion where the conductor layer 12-2 is to be formed is formed. As described with reference to FIG. 12, as viewed from above, the openings O5 and O5′ overlap parts of the portions SL1 and SL2 corresponding to the side surfaces of the hole H2, respectively. Thereby, in the above etching, in the portion corresponding to the hole H2, a portion on one side of the position P1 and a portion on the other side of the position P2 in FIG. 12 are removed by approximately the height ht1. For this reason, as shown in FIG. 14, a hole H5 having a shape corresponding to the sub-portions 12-2A-2 and 12-2A-3 is formed. A hole corresponding to the portion where the conductor layer 12-3 is to be formed is the same as the hole H5 corresponding to the portion where the conductor layer 12-2 is to be formed.

In addition, the conductor layers 12-1, 12-2, and 12-3 are formed to be embedded in the holes H4 and H5 formed by the process described with reference to FIGS. 13 and 14.

The semiconductor device 1 is formed by the process described above.

### 1.3 Effects

According to the first embodiment, it is possible to curb deterioration of breakdown voltage characteristics of the semiconductor device 1. The effects of the embodiment will be described below.

The semiconductor device 1 according to the first embodiment includes the conductor layers 12-1 and 12-2 adjacent to each other in the Y-direction. The conductor layer 12-1 includes the portions 12-1A and 12-1B. The portion 12-1A is a via or plug extending in the Z-direction. The portion 12-1B extends in the X-direction. The portion 12-1A is in contact with the portion 12-1B on the upper side of the portion 12-1A. The conductor layer 12-2 includes the portions 12-2A and 12-2B. The portions 12-2A and 12-2B are aligned in the X-direction to be in contact with each other. The portion 12-2A is adjacent to the portion 12-1A in the Y-direction. The portion 12-2B is in the same layer as the portion 12-1B and extends in the X-direction. The position of the lower surface of the portion 12-2A in the Z-direction is different from the position of the lower surface of the portion 12-2B in the Z-direction. With the above-described configuration, according to the first embodiment, it is possible to curb deterioration of breakdown voltage characteristics of the semiconductor device 1 due to misalignment of the via or plug portion with respect to the wiring portion extending in the X-direction.

The effect of the semiconductor device 1 according to the first embodiment will be supplemented.

A comparative example in which three wirings arranged adjacent to each other in the Y-direction are formed will be described using a dual damascene technique. In the comparative example, the central wiring in the Y-direction has, for example, a via or plug and an extending portion that extends linearly in the X-direction. In addition, two adjacent wirings sandwiching the central wiring in the Y-direction extend linearly in the X-direction. In a manufacturing process for the device according to the comparative example, first, for example, a hole corresponding to the via or plug is formed in the insulator layer. Then, above the hole corresponding to the via or plug, holes corresponding to the two adjacent wirings are formed together with a hole corresponding to the extending portion of the central wiring. Then, three wirings are formed such that conductors are embedded in these holes. In the above-described process, the holes corresponding to the via or plug and the holes corresponding to the extending portion and adjacent wirings are formed in different processes, which may cause the center position of the via or plug in the Y-direction to be misaligned with the center position of the extending portion in the Y-direction (misalignment may occur). In such a case, the via or plug of a central wiring may come closer to one of the two adjacent wirings in the Y-direction. Thereby, breakdown voltage characteristics of the semiconductor device may deteriorate.

In the semiconductor device 1 according to the first embodiment, the conductor layers 12-1 and 12-2 adjacent to each other include the portions 12-1A and 12-2A adjacent to each other in the Y-direction. In the manufacturing method of the semiconductor device 1 according to the first embodiment, as described with reference to FIGS. 5 and 6, the holes H1 and H2 are formed in the portions where the portions 12-1A and 12-2A are to be formed, as shown in FIGS. 7, 8, and 9, by etching using the resist RU1 having the openings O1 and O2 corresponding to the portions 12-1A and 12-2A, respectively. Thereafter, as described using FIGS. 10, 11, and 12, the holes H4 and H5 are formed in the portions where the conductor layers 12-1 and 12-2 are to be formed, as shown in FIGS. 13 and 14, by etching using the resist RU2 having the openings O4 and O5 corresponding to the portions 12-1B and 12-2B, respectively, extending in the X-direction. As described above, in the first embodiment, the portions where the portions 12-1A and 12-2A are to be formed and the portions where the portions 12-1B and 12-2B are to be formed are formed separately. Thereby, even when the center position of the portion 12-1A in the Y-direction is shifted from the center position of the portion 12-1B in the Y-direction, the portion 12-2A adjacent to the portion 12-1A in the Y-direction is also shifted in the same manner, and thus the distance D1 between the portion 12-1A and the conductor layer 12-2 does not change. Thus, deterioration of breakdown voltage characteristics of the semiconductor device 1 is curbed.

### 2. Modification Example of First Embodiment

The above-described first embodiment can be modified in various manners. A semiconductor device according to a modification example of the first embodiment will be described below.

### 2.1 First Modification Example of First Embodiment

In the above-described first embodiment, as shown in FIG. 12, in the manufacturing process, the openings O5 and O5′ overlap a part of the portion SL1 corresponding to one side surface of the hole H2 and a part of the portion SL2 corresponding to the other side surface of the hole H2, respectively, in the Z-direction, but this is not limiting. In the manufacturing process, the opening O5 may entirely overlap the portion SL1, and the opening O5′ may entirely overlap the portion SL2. Hereinafter, the configuration and manufacturing method of a semiconductor device according to a first modification example of the first embodiment will be described in terms of differences from the configuration and manufacturing method of the semiconductor device according to the first embodiment.

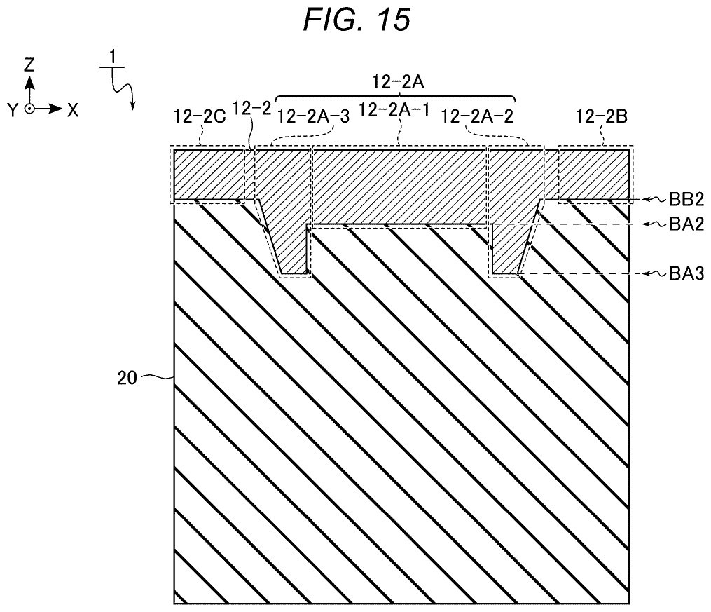

The configuration of the semiconductor device 1 according to the first modification example of the first embodiment will be described with reference to FIG. 15. FIG. 15 is a cross-sectional view showing an example of a portion of the semiconductor device according to the first modification example of the first embodiment. The cross-section shown in FIG. 15 corresponds to the cross-section shown in FIG. 4 of the first embodiment.

The position of the lower surface of the sub-portion 12-2A-1 in the Z-direction is a position BA2. The position BA2 is, for example, below a position BB2 of the lower surface of the portion 12-2B and the lower surface of the portion 12-2C in the Z-direction.

The position of the lower end of the sub-portion 12-2A-2 and the position of the lower end of the sub-portion 12-2A-3 in the Z-direction is a position BA3. The position BA3 is below the positions BA2 and BB2. The sub-portions 12-2A-2 and 12-2A-3 may have lower surfaces that are, for example, substantially parallel to the substrate.

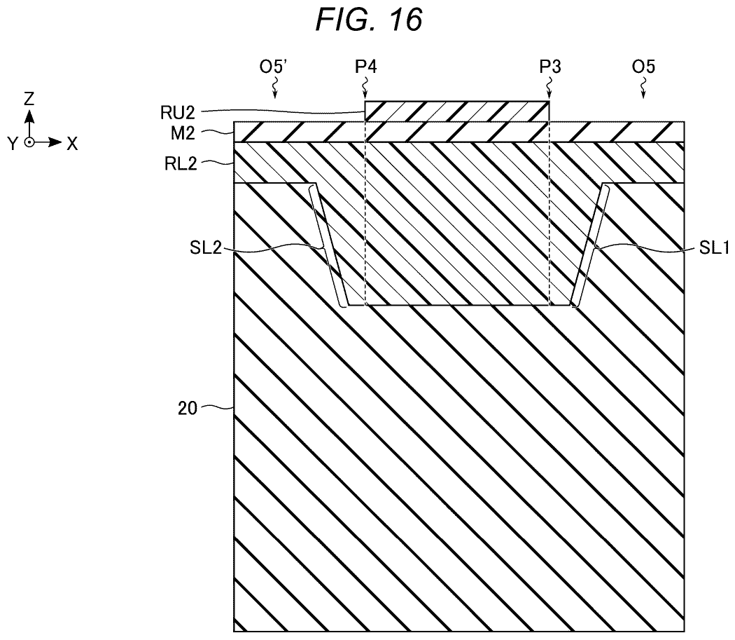

The manufacturing method of the semiconductor device 1 according to the first modification example of the first embodiment is the same as the manufacturing method of the semiconductor device according to the first embodiment, except for the process described with reference to FIGS. 10, 11, and 12 of the first embodiment. The manufacturing method of the semiconductor device 1 according to the first modification example of the first embodiment will be described below with reference to FIG. 16. FIG. 16 corresponds to the cross-section shown in FIG. 15.

As shown in FIG. 16, the opening O5 overlaps the entire portion SL1. In the XZ cross-section, a position P3 on the other side of the opening O5 in the X-direction is located on the other side of the portion SL1 in the X-direction. Thereby, the opening O5 overlaps a part of the portion corresponding to the bottom surface of the hole H2. In addition, the opening O5′ overlaps the entire portion SL2. In the XZ cross-section, a position P4 on one side of the opening O5′ in the X-direction is located on one side of the portion SL2 in the X-direction. Thereby, the opening O5′ overlaps a part of the portion corresponding to the bottom surface of the hole H2. The position P4 is located on the other side of the position P3 in the X-direction. Although an XZ cross-section including openings O6 and O6′ is not illustrated, the XZ cross-section including the openings O6 and O6′ is substantially equivalent to the XZ cross-section including the openings O5 and O5′ shown in FIG. 16.

In a process similar to that described in FIGS. 13 and 14 of the first embodiment, a portion on one side of the position P3 in FIG. 16 and a portion on the other side of the position P4 in FIG. 16 are removed using the resist RU2 having the openings O5 and O5′ as described above. Thereby, a hole corresponding to the conductor layer 12-2 according to the first modification example of the first embodiment is formed.

In this manner, the semiconductor device 1 according to the first modification example of the first embodiment is manufactured.

The first modification example of the first embodiment also provides the same effects as those in the first embodiment.

### 2.2 Second Modification Example of First Embodiment

In the above-described first embodiment and the first modification example of the first embodiment, a case where the lower surface of the sub-portion 12-2A-1 is below the lower surfaces of the portions 12-2B and 12-2C is described, but this is not limiting. The lower surface of the sub-portion 12-2A-1 may be positioned above the lower surfaces of the portions 12-2B and 12-2C. Hereinafter, the configuration and manufacturing method of a semiconductor device according to a second modification example of the first embodiment will be described in terms of differences from the configuration and manufacturing method of the semiconductor device according to the first modification example of the first embodiment.

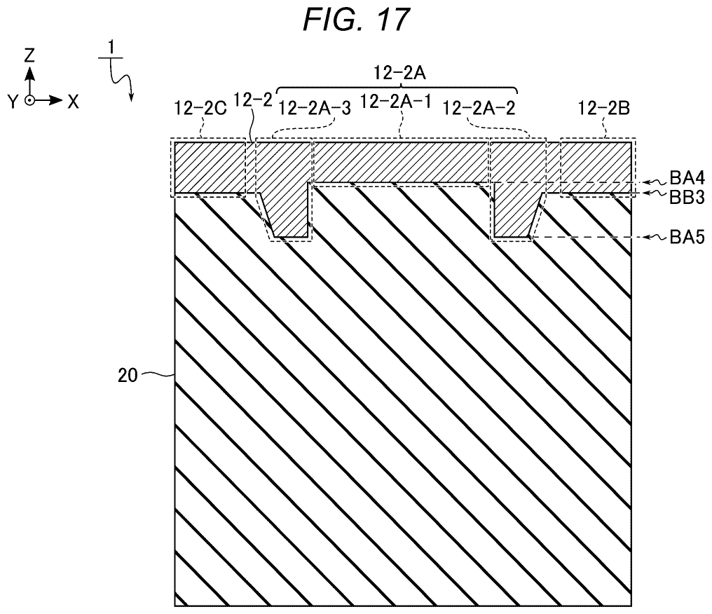

The configuration of the semiconductor device 1 according to the second modification example of the first embodiment will be described with reference to FIG. 17. FIG. 17 is a cross-sectional view showing an example of a portion of the semiconductor device according to the second modification example of the first embodiment. The cross-section shown in FIG. 17 corresponds to the cross-section shown in FIG. 4 of the first embodiment.

In the second modification example of the first embodiment, the position of the lower surface of the sub-portion 12-2A-1 in the Z-direction is a position BA4. In the Z-direction, the position BA4 is, for example, at a height equal to or higher than a position BB3 of the lower surface of the portion 12-2B and the lower surface of the portion 12-2C.

In the Z-direction, the position of the lower end of the sub-portion 12-2A-2 and the lower end of the sub-portion 12-2A-3 is a position BA5. The position BA5 is below the positions BB3 and BA4.

The manufacturing method of the semiconductor device 1 according to the second modification example of the first embodiment can be the same as that in the first modification example of the first embodiment, except that the depth of the hole H2 is different in the process corresponding to the process described with reference to FIGS. 7, 8, and 9 of the first embodiment.

The second modification example of the first embodiment also provides the same effects as those in the first embodiment.

### 2.3 Third Modification Example of First Embodiment

In the above-described first embodiment, the first modification example of the first embodiment, and the second modification example of the first embodiment, a case where the lower surface of the portion 12-2A and the lower surface of the portion 12-3A are formed above the lower surface of the portion 12-1A due to a microloading effect in the manufacturing process is described, but this is not limiting. The conductor layers 12-1, 12-2, and 12-3 may be formed such that the lower surface of the portion 12-2A and the lower surface of the portion 12-3A are positioned above the lower surface of the portion 12-1A due to a stopper. Hereinafter, the configuration and manufacturing method of a semiconductor device according to a third modification example of the first embodiment will be described in terms of differences from the configuration and manufacturing method of the semiconductor device according to the first embodiment.

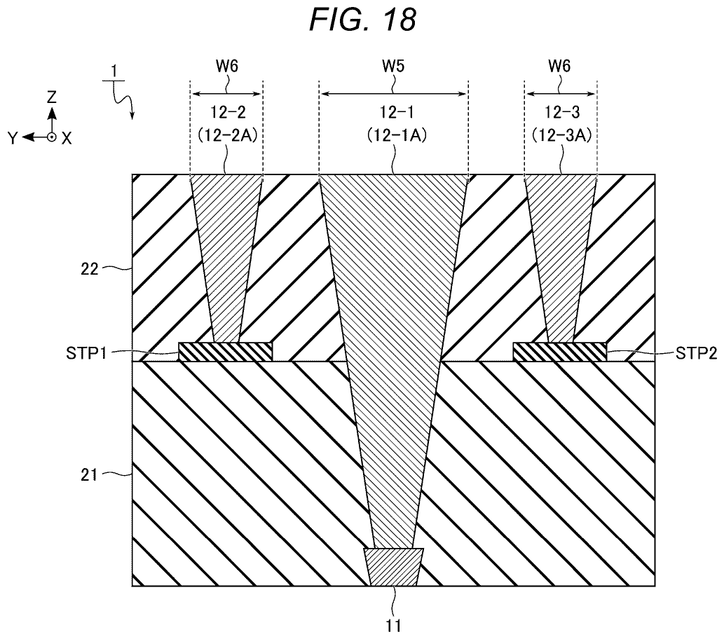

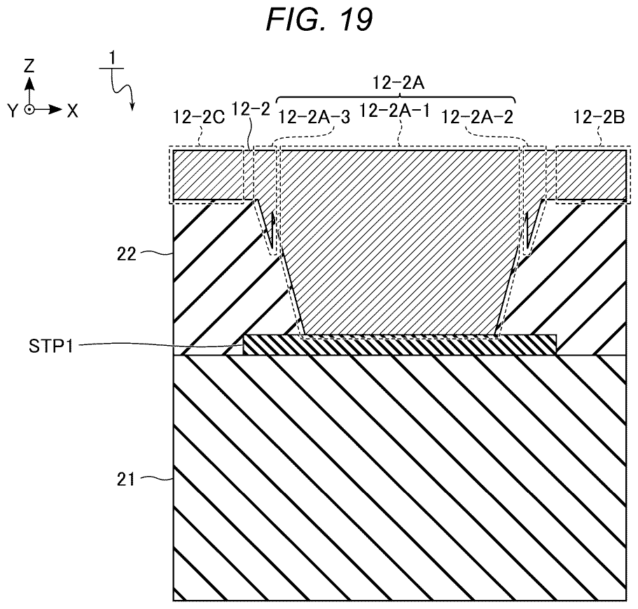

The configuration of the semiconductor device 1 according to the third modification example of the first embodiment will be described with reference to FIGS. 18 and 19. FIGS. 18 and 19 are cross-sectional views showing an example of a portion of the semiconductor device according to the third modification example of the first embodiment. The cross-sections shown in FIGS. 18 and 19 correspond to the cross-sections shown in FIGS. 1 and 4 of the first embodiment, respectively.

The configuration of the semiconductor device 1 in the YZ cross-section will be described with reference to FIG. 18.

The semiconductor device 1 includes conductor layers 11, 12-1, 12-2, and 12-3, stoppers STP1 and STP2, and insulator layers 21 and 22.

The insulator layers 21 and 22 are provided above the substrate in this order. The conductor layer 11 is provided in the insulator layer 21. The upper surface of the conductor layer 11 is positioned below the upper surface of the insulator layer 21. The conductor layers 12-2 and 12-3 and the stoppers STP1 and STP2 are provided in the insulator layer 22. The conductor layer 12-1 is provided in the insulator layers 21 and 22.

The stoppers STP1 and STP2 are provided on the upper surface of the insulator layer 21. The stoppers STP1 and STP2 are provided corresponding to the conductor layers 12-2 and 12-3, respectively. The stoppers STP1 and STP2 are, for example, insulators. The stoppers STP1 and STP2 may be conductors.

The portion 12-2A is in contact with the upper surface of the stopper STP1. The portion 12-3A is in contact with the upper surface of the stopper STP2.

As in the first embodiment, FIG. 18 shows a case where a width W6 of each of the portions 12-2A and 12-3A in the Y-direction is smaller than a width W5 of the portion 12-1A in the Y-direction, but this is not limiting. The width W6 of each of the portions 12-2A and 12-3A in the Y-direction may be equal to or larger than the width W5 of the portion 12-1A in the Y-direction.

In addition, as shown in FIG. 19, the lower surface of the sub-portion 12-2A-1 of the portion 12-2A is in contact with the stopper STP1. Although not shown in the drawing, the structure of the conductor layer 12-3 in the XZ cross-section is substantially the same as the structure of the conductor layer 12-2 shown in FIG. 19.

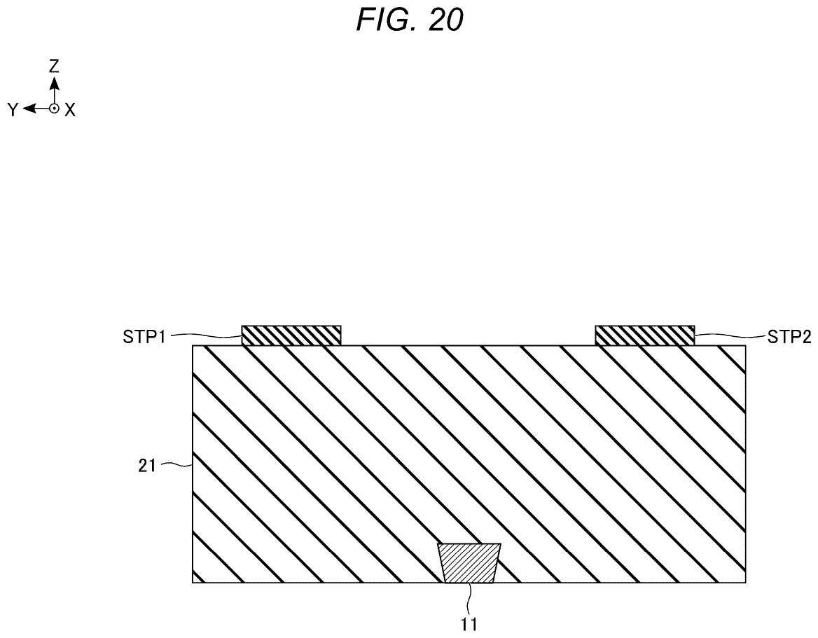

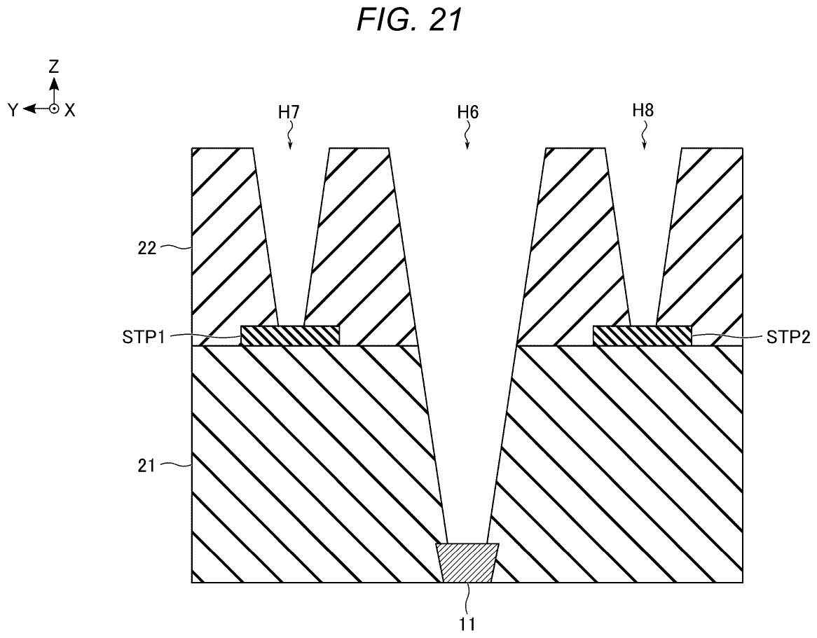

A manufacturing method of the semiconductor device 1 according to the third modification example of the first embodiment will be described with reference to FIGS. 20 and 21. FIGS. 20 and 21 are cross-sectional views showing an example of a manufacturing method of the semiconductor device according to the third modification example of the first embodiment. FIGS. 20 and 21 correspond to the cross-section shown in FIG. 18.

First, the conductor layer 11 and the insulator layer 21 are formed above the substrate. Then, as shown in FIG. 20, the stoppers STP1 and STP2 are formed on the upper surface of the insulator layer 21. More specifically, for example, an insulator is formed entirely on the upper surface of the insulator layer 21. Then, etching is performed on the insulator using a mask having openings that surround portions where the stoppers STP1 and STP2 are to be formed. In this manner, the stoppers STP1 and STP2 are formed on the upper surface of the insulator layer 21.

Then, the insulator layer 22 is formed on the upper surfaces of the stoppers STP1 and STP2 and on the upper surface of the insulator layer 21. Then, a resist and an intermediate layer are formed in the same manner as in the process described with reference to FIGS. 5 and 6 of the first embodiment. In addition, etching is executed using the resist and the intermediate layer in the same manner as in the process described with reference to FIGS. 7, 8, and 9 of the first embodiment. After the etching, the resist and the intermediate layer are removed. Through the above processing, holes H6, H7, and H8 are formed as shown in FIG. 21. The holes H6, H7, and H8 correspond to portions 12-1A, 12-2A, and 12-3A, respectively. The holes H7 and H8 are formed corresponding to the stoppers STP1 and STP2. Thereby, in the above etching, the formation of the holes H7 and H8 is stopped on the upper surfaces of the stoppers STP1 and STP2 by the stoppers STP1 and STP2. The upper surfaces of the stoppers STP1 and STP2 are exposed at the bottom surfaces of the holes H7 and H8.

The other processes are substantially the same as those in the manufacturing method of the semiconductor device according to the first embodiment, except that processing is executed on the insulator layers 21 and 22 instead of the insulator layer 20.

The third modification example of the first embodiment also provides the same effects as those in the first embodiment.

### 2.4 Fourth Modification Example of First Embodiment

In the above-described third modification example of the first embodiment, a case where the stopper STP is provided above the conductor layer 11 is described, but this is not limiting. The stopper STP may be provided in the same layer as the conductor layer 11. Hereinafter, the configuration and manufacturing method of a semiconductor device according to a fourth modification example of the first embodiment will be described in terms of differences from the configuration and manufacturing method of the semiconductor device according to the third modification example of the first embodiment.

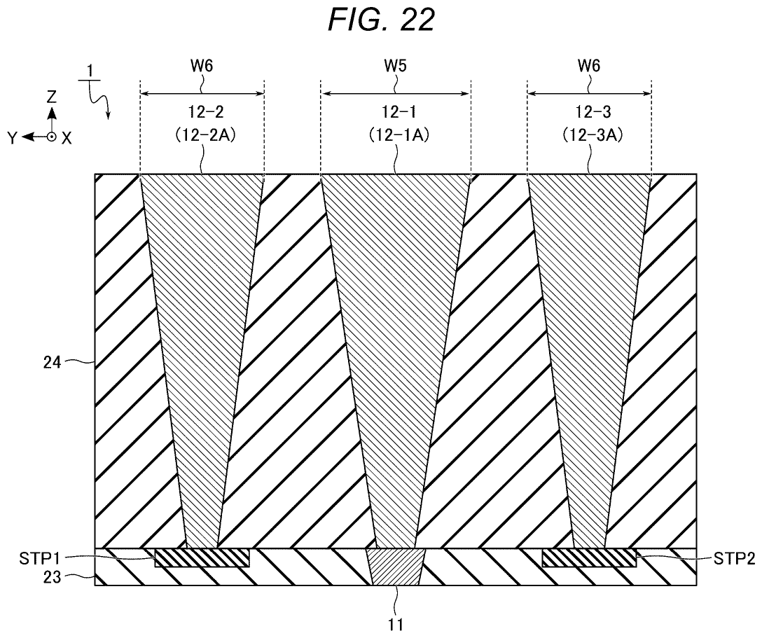

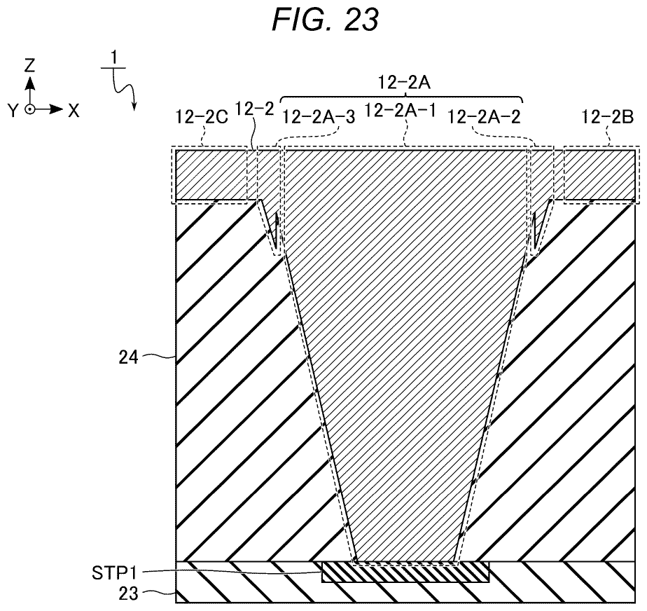

The configuration of the semiconductor device 1 according to the fourth modification example of the first embodiment will be described with reference to FIGS. 22 and 23. FIGS. 22 and 23 are cross-sectional views showing an example of a portion of the semiconductor device according to the fourth modification example of the first embodiment. The cross-sections shown in FIGS. 22 and 23 correspond to the cross-sections shown in FIGS. 1 and 4 of the first embodiment, respectively.

The configuration of the semiconductor device 1 in the YZ cross-section will be described with reference to FIG. 22.

The semiconductor device 1 includes conductor layers 11, 12-1, 12-2, and 12-3, insulator layers 23 and 24, and stoppers STP1 and STP2.

The insulator layers 23 and 24 are provided above the substrate in this order. The conductor layer 11 and the stoppers STP1 and STP2 are provided in the insulator layer 23. The upper surface of the insulator layer 23, the upper surface of the conductor layer 11, and the upper surfaces of the two stoppers STP are provided to be flush with each other, for example. The two stoppers STP are provided in the same layer as the conductor layer 11.

The conductor layers 12-1, 12-2, and 12-3 are provided in the insulator layer 24. The lower surface of the insulator layer 24, the lower surface of the conductor layer 12-1, the lower surface of the conductor layer 12-2, and the lower surface of the conductor layer 12-3 are provided to be flush with each other.

As shown in FIG. 23, in the XZ cross-section including the conductor layer 12-2, the lower surface of the sub-portion 12-2A-1 is in contact with the stopper STP1, as in the third modification example of the first embodiment. Although not shown in the drawing, the structure of the conductor layer 12-3 in the XZ cross-section is substantially equivalent to the structure of the conductor layer 12-2 shown in FIG. 23.

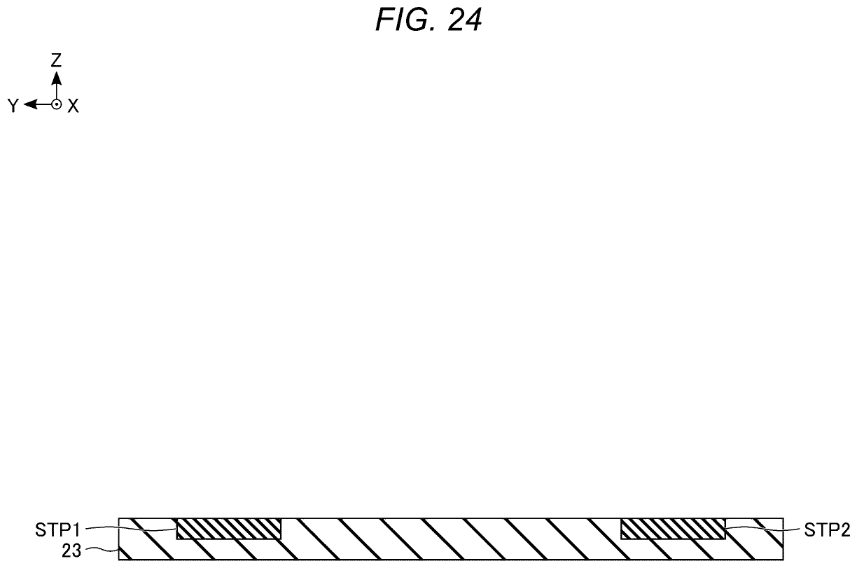

The manufacturing method of the semiconductor device 1 according to the fourth modification example of the first embodiment will be described with reference to FIG. 24. FIG. 24 is a cross-sectional view showing an example of a manufacturing method of the semiconductor device according to the fourth modification example of the first embodiment. FIG. 24 corresponds to the cross-section shown in FIG. 22.

First, as shown in FIG. 24, the insulator layer 23 and the stoppers STP1 and STP2 are formed above the substrate. The upper surfaces of the insulator layer 23 and the stoppers STP1 and STP2 are formed to be flush with each other.

The other processes are the same as those in the third modification example of the first embodiment, except that the depths of the holes corresponding to the portions 12-2A and 12-3A are different, and that processing is performed on the insulator layer 24 instead of the insulator layers 21 and 22.

The fourth modification example of the first embodiment also provides the same effects as those in the first embodiment.

### 2.5 Fifth Modification Example of First Embodiment

In the above-described fourth modification example of the first embodiment, the stoppers STP1 and STP2 are provided in the same layer as the conductor layer 11, but this is not limiting. For example, a conductor provided by the same process as the conductor layer 11 may be provided as a stopper. Hereinafter, the configuration and manufacturing method of a semiconductor device according to a fifth modification example of the first embodiment will be described in terms of differences from the configuration and manufacturing method of the semiconductor device according to the first embodiment.

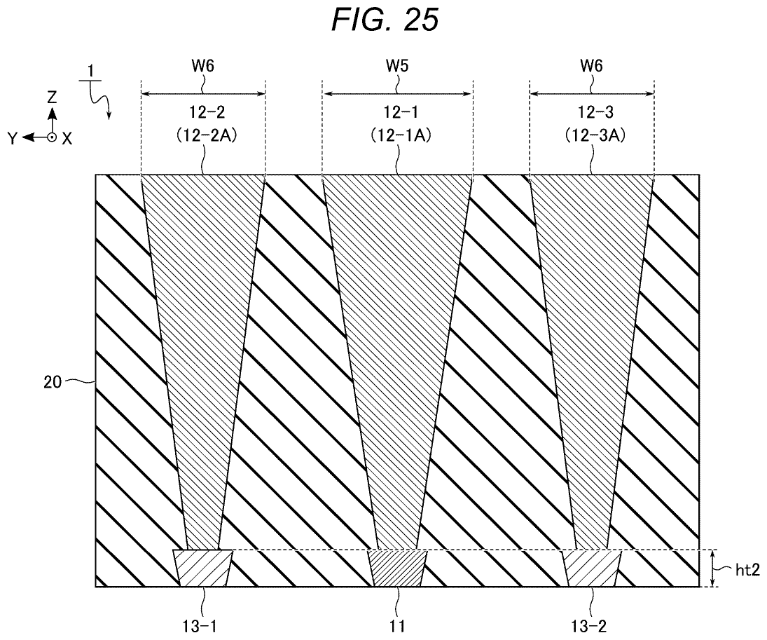

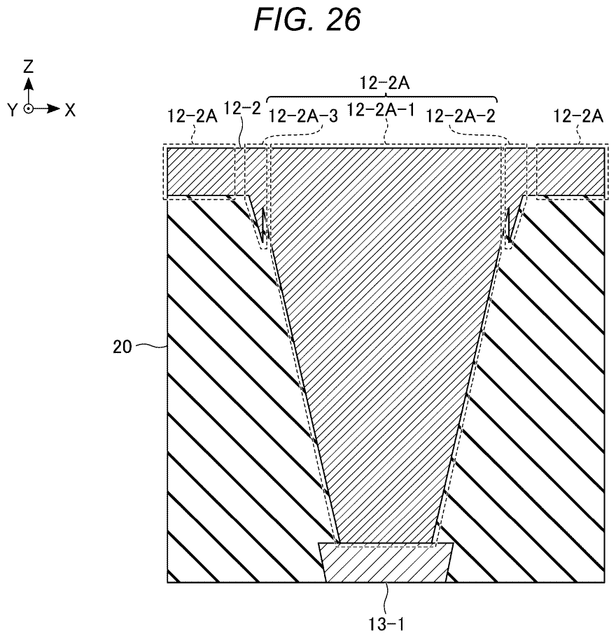

The configuration of the semiconductor device 1 according to the fifth modification example of the first embodiment will be described with reference to FIGS. 25 and 26. FIGS. 25 and 26 are cross-sectional views showing an example of a portion of the semiconductor device according to the fifth modification example of the first embodiment. The cross-sections shown in FIGS. 25 and 26 correspond to the cross-sections shown in FIGS. 1 and 4 of the first embodiment, respectively.

The semiconductor device 1 includes conductor layers 11, 12-1, 12-2, 12-3, 13-1, and 13-2, and an insulator layer 20.

The conductor layers 13-1 and 13-2 are provided corresponding to the conductor layers 12-2 and 12-3, respectively. The conductor layers 13-1 and 13-2 are provided in the same layer as the conductor layer 11. Further, in the Z-direction, the position of the upper surface of the conductor layer 13-1 and the position of the upper surface of the conductor layer 13-2 are substantially the same as the position of the upper surface of the conductor layer 11. Further, in the Z-direction, the position of the lower surface of the conductor layer 13-1 and the position of the lower surface of the conductor layer 13-2 are substantially the same as the position of the lower surface of the conductor layer 11. With the above-described configuration, the conductor layers 11, 13-1, and 13-2 have approximately a height ht2.

The conductor layer 12-2 is in contact with the upper surface of conductor layer 13-1. For example, the conductor layer 13-1 is provided to be separated from a conductor other than the conductor layer 12-2 in the semiconductor device 1.

The conductor layer 12-3 is in contact with the upper surface of the conductor layer 13-2. For example, the conductor layer 13-2 is provided to be separated from a conductor other than the conductor layer 12-3 in the semiconductor device 1.

The configuration of the semiconductor device 1 in the XZ cross-section including the conductor layer 12-2 is substantially the same as the structure according to the fourth modification example of the first embodiment, except that conductor layer 13-1 is provided instead of a stopper, as shown in FIG. 26.

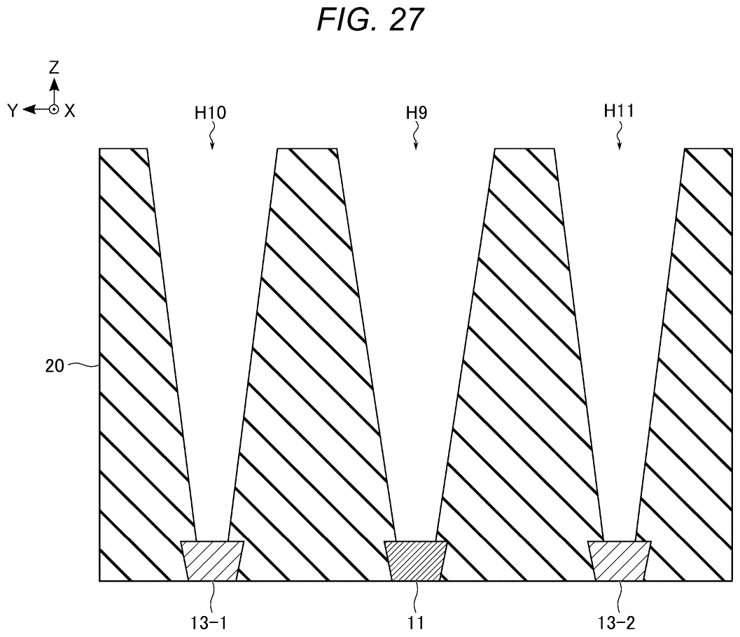

A manufacturing method of the semiconductor device 1 according to the fifth modification example of the first embodiment will be described with reference to FIG. 27. FIG. 27 is a cross-sectional view showing an example of a manufacturing method of the semiconductor device according to the fifth modification example of the first embodiment. The cross-section shown in FIG. 27 corresponds to the cross-section shown in FIG. 25.

In the manufacturing method of the semiconductor device 1 according to the fifth modification example of the first embodiment, in a process corresponding to the process described with reference to FIGS. 7, 8, and 9 of the first embodiment, the formation of holes H9, H10, and H11 corresponding to the portions 12-1A, 12-2A, and 12-3A is stopped by the conductor layers 11, 13-1, and 13-2 formed in the same layers, respectively.

The other processes are the same as those in the first embodiment.

The fifth modification example of the first embodiment also provides the same effects as those in the first embodiment.

### 2.6 Sixth Modification Example of First Embodiment

In the above-described first embodiment, a case where the portion 12-1A is connected to the upper surface of the conductor layer 11 provided above the substrate is described, but this is not limiting. The portion 12-1A may be provided so as to be in contact with the substrate. Hereinafter, the configuration and manufacturing method of a semiconductor device according to a sixth modification example of the first embodiment will be described in terms of differences from the configuration and manufacturing method of the semiconductor device according to the first embodiment.

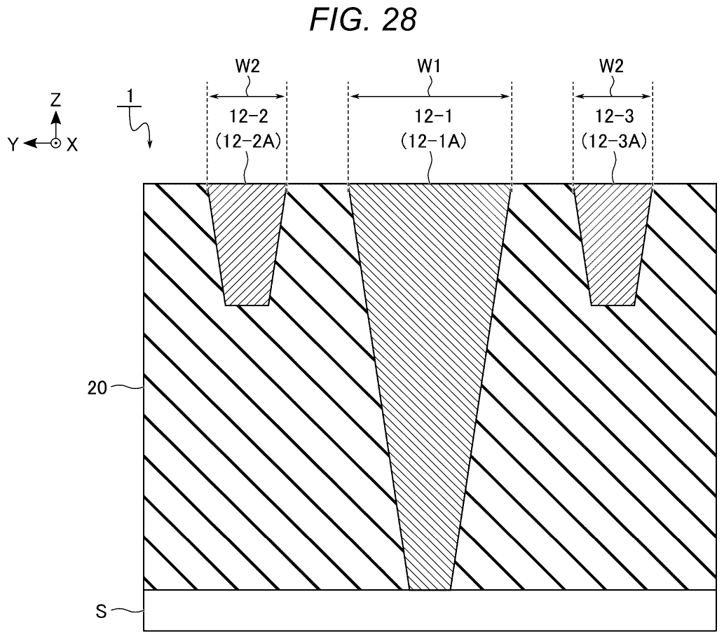

The configuration of the semiconductor device 1 according to the sixth modification example of the first embodiment will be described with reference to FIG. 28. FIG. 28 is a cross-sectional view showing an example of a portion of the semiconductor device according to the sixth modification example of the first embodiment. The cross-section shown in FIG. 28 corresponds to the cross-section shown in FIG. 1 of the first embodiment.

As shown in FIG. 28, in the sixth modification example of the first embodiment, the insulator layer 20 is provided on the upper surface of a substrate S. In addition, the conductor layer 12-1 is provided such that the portion 12-1A is in contact with the substrate S. The portion 12-1A is in contact with, for example, an electrode or an impurity diffusion region provided on the substrate S.

The other configurations can be the same as those of the semiconductor device according to the first embodiment.

A manufacturing method of the semiconductor device 1 according to the sixth modification example of the first embodiment is the same as the manufacturing method of the semiconductor device according to the first embodiment, except that the substrate S functions as a stopper instead of the conductor layer in the same process as the process described with reference to FIGS. 7, 8, and 9 of the first embodiment.

The sixth modification example of the first embodiment also provides the same effects as those in the first embodiment.

### 3. Second Embodiment

In the above-described first embodiment, an example using a dual damascene technique in which a via or plug and a wiring layer are integrally formed is described, but this is not limiting. For example, a structure in which a via or plug and a wiring layer are separately provided using a single damascene technique may be used.

### 3.1 Configuration

The configuration of a semiconductor device according to a second embodiment will be mainly described in terms of differences from the configuration of the semiconductor device according to the first embodiment. The configurations of portions provided in the semiconductor device will be described below.

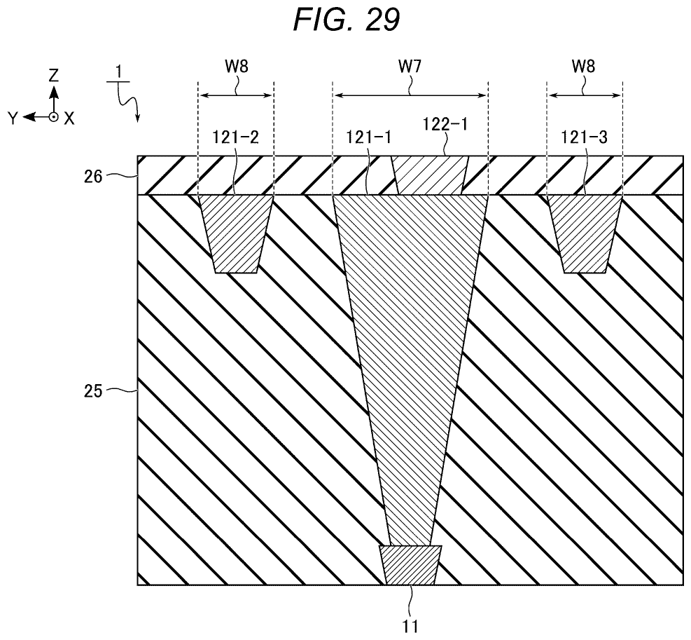

The configuration of the semiconductor device 1 in the YZ cross-section will be described with reference to FIG. 29. FIG. 29 is a cross-sectional view showing an example of a portion of the semiconductor device according to the second embodiment. The cross-section of FIG. 29 corresponds to the cross-section of FIG. 1 of the first embodiment.

The semiconductor device 1 includes conductor layers 11, 121-1, 121-2, 121-3, and 122-1, and insulator layers 25 and 26. The conductor layers 11, 121-1, 121-2, 121-3, and 122-1 function as wirings that are electrically connected to a circuit provided on a substrate (not shown), for example.

The conductor layer 121-1 is provided above the conductor layer 11. The lower surface of the conductor layer 121-1 is electrically connected, for example, to the upper surface of the conductor layer 11. The conductor layer 121-1 extends in the Z-direction. The conductor layer 121-1 functions as a via or plug electrically connected to the conductor layer 11.

The conductor layers 121-2 and 121-3 are provided, for example, adjacent to the conductor layer 121-1 in the Y-direction. The conductor layer 121-1 is sandwiched between the conductor layers 121-2 and 121-3 in the Y-direction. A width W7 in the Y-direction at an upper end of the conductor layer 121-1 is larger than a width W8 in the Y-direction at upper ends of the conductor layers 121-2 and 121-3. The lower surfaces of the conductor layers 121-2 and 121-3 in the Z-direction are positioned, for example, above the lower surface of the conductor layer 121-1.

The conductor layers 11, 121-1, 121-2, and 121-3 are provided in an insulator layer 25. The upper surfaces of the conductor layers 121-1, 121-2, and 121-3 are provided, for example, to be flush with the upper surface of the insulator layer 25.

The conductor layer 122-1 is provided on the upper surface of the conductor layer 121-1. As will be described later, the conductor layer 122-1 extends in the X-direction in a cross-section not shown in FIG. 29. The conductor layer 122-1 is provided, for example, in the same layer as an insulator layer 26. The upper and lower surfaces of the conductor layer 122-1 are provided to be flush with the upper and lower surfaces of the insulator layer 26.

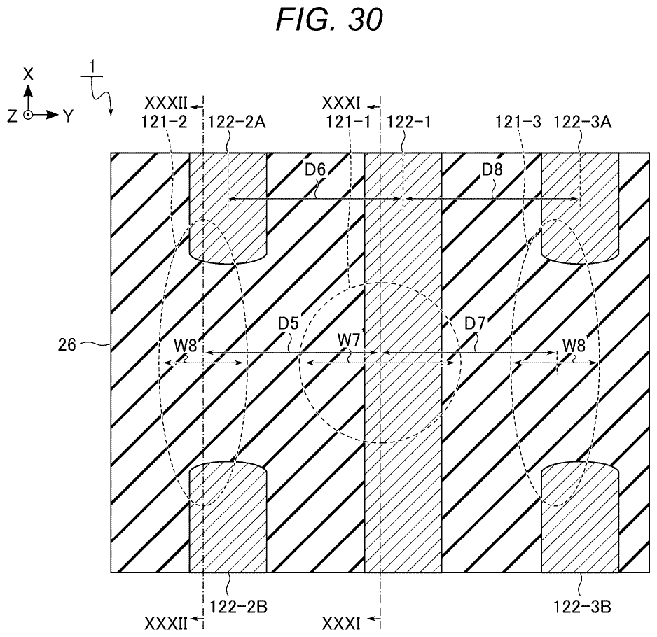

The configuration of the semiconductor device 1 in the XY cross-section will be described with reference to FIG. 30. FIG. 30 is a cross-sectional view showing an example of a portion of the semiconductor device according to the second embodiment. FIG. 30 shows the configuration of a portion of the semiconductor device 1 in the XY cross-section at a position equivalent to the upper surface of the conductor layer 122-1.

In FIG. 30, regions in which the conductor layers 121-1, 121-2, and 121-3 are provided are shown by dotted lines. The conductor layer 121-1 has a circular shape when viewed from above. The conductor layer 121-2 has a substantially elliptical shape with the X-direction as the major axis direction when viewed from above. The conductor layer 121-3 has a substantially elliptical shape with the X-direction as the major axis direction when viewed from above. The conductor layers 121-1, 121-2, and 121-3 are provided to be aligned in the Y-direction.

The semiconductor device 1 further includes conductor layers 122-2A, 122-2B, 122-3A, and 122-3B. The conductor layers 122-2A, 122-2B, 122-3A, and 122-3B are provided in the same layer as the insulator layer 26, similar to the conductor layer 122-1. The conductor layers 122-2A, 122-2B, 122-3A, and 122-3B function as wirings that are electrically connected to a circuit provided on a substrate (not shown), for example.

The conductor layer 122-1 extends in the X-direction so as to overlap a portion of the conductor layer 121-1 when viewed from above.

The conductor layers 122-2A and 122-2B are provided corresponding to the conductor layer 121-2. The conductor layers 122-2A and 122-2B each extend in the X-direction. The conductor layers 122-2A and 122-2B are, for example, provided on substantially the same straight line. The conductor layer 122-2A is provided to overlap a portion of the conductor layer 121-2 on one side in the X-direction when viewed from above. The conductor layer 122-2B is provided to overlap a portion of the conductor layer 121-2 on the other side in the X-direction when viewed from above.

The conductor layers 122-3A and 122-3B are provided corresponding to the conductor layer 121-3. The conductor layers 122-3A and 122-3B each extend in the X-direction. The conductor layers 122-3A and 122-3B are, for example, provided on substantially the same straight line. The conductor layer 122-3A is provided to overlap a portion of the conductor layer 121-3 on one side in the X-direction when viewed from above. The conductor layer 122-3B is provided to overlap a portion of the conductor layer 121-3 on the other side in the X-direction when viewed from above.

The center of the conductor layer 121-1 in the Y-direction and the center of the conductor layer 122-1 in the Y-direction may be shifted in the Y-direction, or may be aligned in the Y-direction. FIG. 30 shows an example of a case where the center of the conductor layer 121-1 in the Y-direction is shifted in the Y-direction with respect to the center of the conductor layer 122-1 in the Y-direction. An arrangement relationship between the conductor layers 121-2, 122-2A, and 122-2B and an arrangement relationship between the conductor layers 121-3, 122-3A, and 122-3B are respectively similar to the arrangement relationship between the conductor layers 121-1 and 122-1, for example. When the center of the conductor layer 121-1 in the Y-direction is provided to be shifted to one side or the other side in the Y-direction with respect to the center of the conductor layer 122-1 in the Y-direction, the center of the conductor layer 121-2 in the Y-direction is provided to be shifted to one side or the other side in the Y-direction with respect to the centers of the conductor layers 122-2A and 122-2B in the Y-direction. In this case, the center of the conductor layer 121-3 in the Y-direction is shifted to one side or the other side in the Y-direction with respect to the centers of the conductor layers 122-3A and 122-3B in the Y-direction. When the center of the conductor layer 121-1 in the Y-direction is aligned with the center of the conductor layer 122-1 in the Y-direction, the center of the conductor layer 121-2 in the Y-direction is aligned with the centers of the conductor layers 122-2A and 122-2B in the Y-direction. In this case, the center of the conductor layer 121-3 in the Y-direction is aligned in the Y-direction with the centers of the conductor layers 122-3A and 122-3B in the Y-direction.

Further, a distance D5 between the center of the conductor layer 121-1 in the Y-direction and the center of the conductor layer 121-2 in the Y-direction is substantially equal to a distance D6 between the center of the conductor layer 122-1 in the Y-direction and the centers of the conductor layers 122-2A and 122-2B in the Y-direction. Further, a distance D7 between the center of the conductor layer 121-1 in the Y-direction and the center of the conductor layer 121-3 in the Y-direction is substantially equal to a distance D8 between the center of the conductor layer 122-1 in the Y-direction and the centers of the conductor layers 122-3A and 122-3B in the Y-direction.

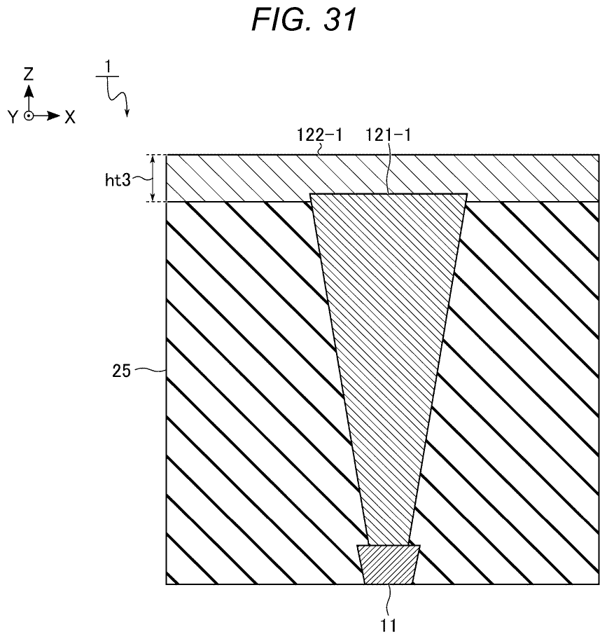

The configuration of the semiconductor device 1 in the XZ cross-section including the conductor layers 121-1 and 122-1 will be described with reference to FIG. 31. FIG. 31 is a cross-sectional view taken along line XXXI-XXXI in FIG. 30, showing an example of a portion of the semiconductor device according to the second embodiment.

In the XZ cross-section, the conductor layer 121-1 is in contact with the upper surface of the conductor layer 11, similar to the configuration of the conductor layer 121-1 in the YZ cross-section in FIG. 29. The position of the lower surface of the conductor layer 122-1 is, for example, at a height higher than the positions of the lower surfaces of the other portions in the portion in contact with the conductor layer 121-1. Although not shown in FIG. 31, the upper surface of the conductor layer 122-1 is provided to be flush with the upper surface of the insulator layer 26, for example. The conductor layer 122-1 has approximately a height ht3 in the Z-direction.

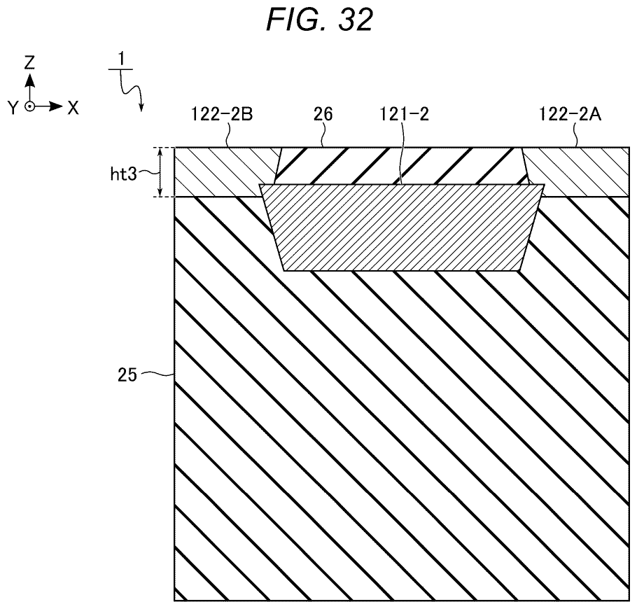

The configuration of the semiconductor device 1 in the XZ cross-section including the conductor layers 121-2, 122-2A, and 122-2B will be described with reference to FIG. 32. FIG. 32 is a cross-sectional view taken along line XXXII-XXXII in FIG. 30, showing an example of a portion of the semiconductor device according to the second embodiment.

The conductor layer 121-2 has, for example, upper and lower surfaces that are substantially parallel to the substrate.

The upper surface of the conductor layer 122-2A, the upper surface of the conductor layer 122-2B, and the upper surface of the insulator layer 26 are provided to be flush with each other. The lower surface of the conductor layer 122-2A and the lower surface of the conductor layer 122-2B are, for example, positioned below the upper surface of the conductor layer 121-2. In the Z-direction, the position of the lower surface of the conductor layer 122-2A and the position of the lower surface of the conductor layer 122-2B are, for example, equivalent to the position of the lower surface of the conductor layer 122-1. With the above-described configuration, the conductor layers 122-2A and 122-2B have approximately a height ht3 in the Z-direction, similar to the conductor layer 122-1.

The conductor layers 121-2 and 122-2A are in contact with each other in a region where the conductor layer 121-2 and the conductor layer 122-2A overlap each other in the Z-direction. The conductor layers 121-2 and 122-2B are in contact with each other in a region where the conductor layer 121-2 and the conductor layer 122-2B overlap each other in the Z-direction.

Although not shown in the drawing, the structures of the conductor layers 121-3, 122-3A, and 122-3B in the XZ cross-section are substantially the same as the structures of the conductor layers 121-2, 122-2A, and 122-2B shown in FIG. 32.

### 3.2 Manufacturing Method

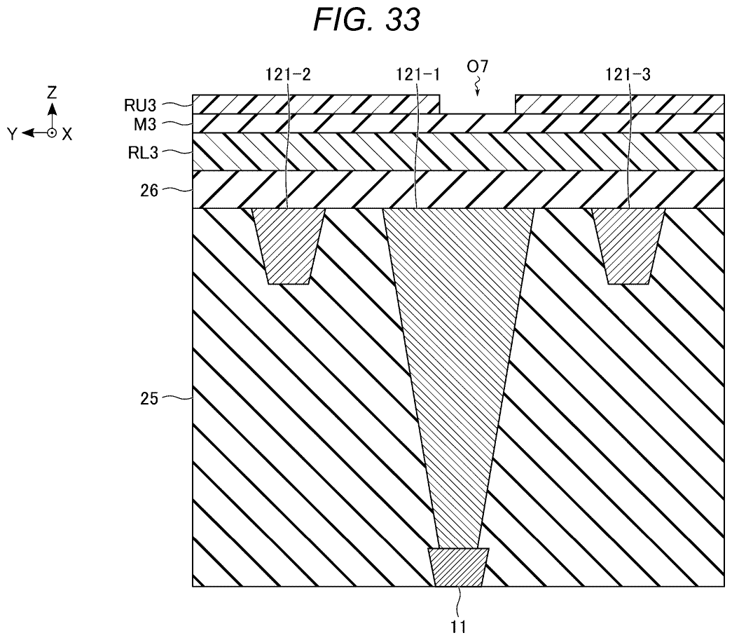

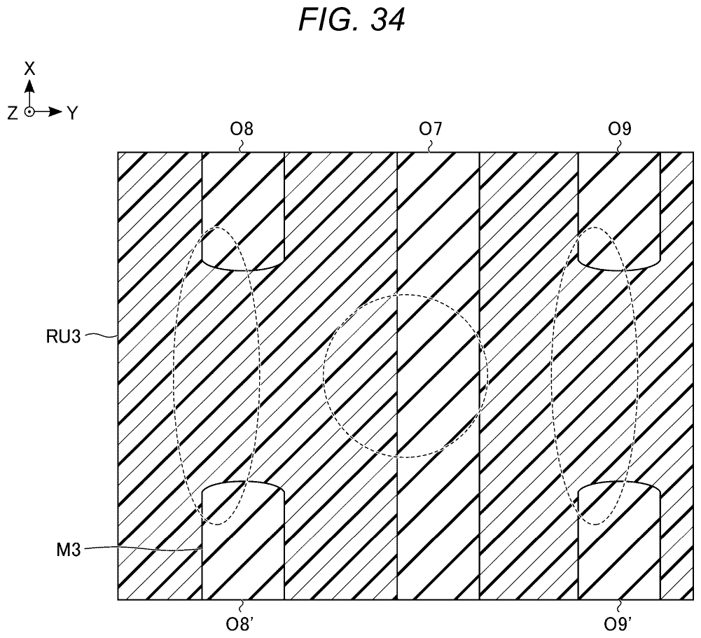

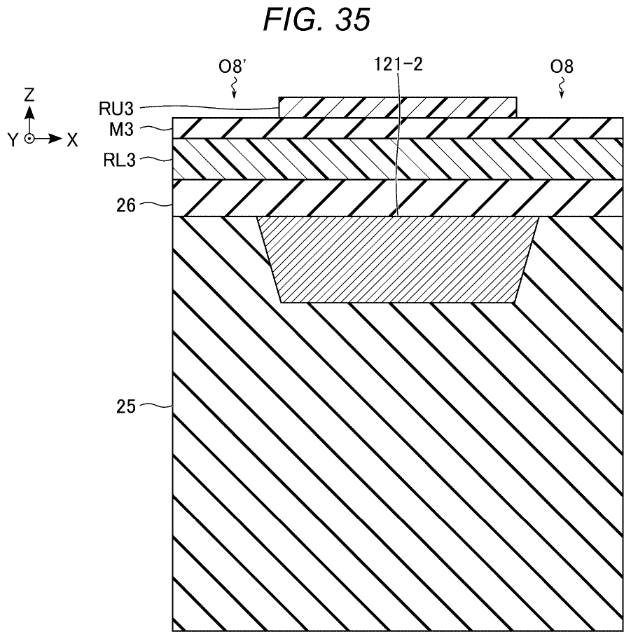

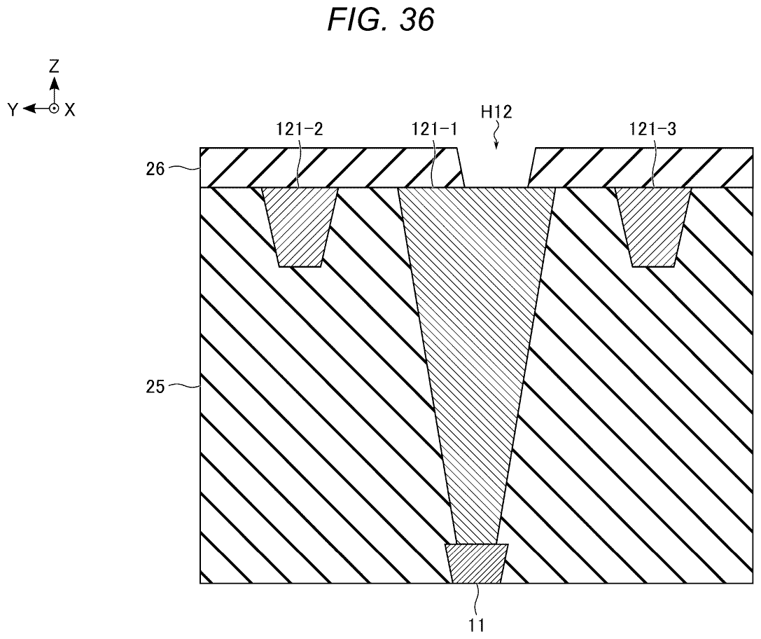

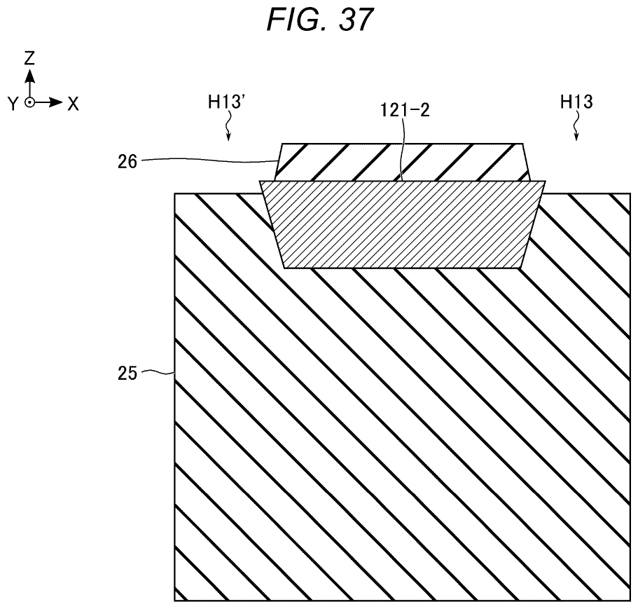

A manufacturing method of the semiconductor device 1 will be described with reference to FIGS. 33, 34, 35, 36, and 37. FIG. 33 and FIGS. 35 to 37 are cross-sectional views showing an example of a manufacturing method of the semiconductor device according to the second embodiment. FIG. 34 is a top view showing an example of the manufacturing method of the semiconductor device according to the second embodiment. The cross-sectional views shown in FIGS. 33 and 36 show a region corresponding to FIG. 29. The view shown in FIG. 34 is a top view of a region corresponding to FIG. 30 as viewed from above. The cross-sectional views shown in FIGS. 35 and 37 show a region corresponding to FIG. 32.

First, holes corresponding to the conductor layers 121-1, 121-2, and 121-3 are formed in the insulator layer 25 through a process similar to the process for forming the holes H1, H2, and H3 described with reference to FIGS. 7, 8, and 9 of the first embodiment. In addition, the conductor layers 121-1, 121-2, and 121-3 are formed to be embedded in the formed holes.

Then, as shown in FIGS. 33, 34, and 35, the insulator layer 26, a resist RL3, an intermediate layer M3, and a resist RU3 are stacked in this order on the upper surface of the insulator layer 25, the upper surface of the conductor layer 121-1, the upper surface of the conductor layer 121-2, and the upper surface of the conductor layer 121-3. The resist RU3 has openings O7, O8, O8′, O9, and O9′ substantially equivalent to the openings O4, O5, O5′, O6, and O6′ of the resist RU2 in the process described with reference to FIGS. 10, 11, and 12 of the first embodiment. The openings O7, O8, O8′, O9, and O9′ correspond to the portions where the conductor layers 122-1, 122-2A, 122-2B, 122-3A, and 122-3B are to be formed, respectively.

Then, portions of the insulator layers 25 and 26 are removed together with the resist RL3 and the intermediate layer M3 as in the first embodiment by etching using the resist RL3, the intermediate layer M3, and the resist RU3 formed as described above. After the etching, the resist RL3, the intermediate layer M3, and the resist RU3 are also removed. Through the above processing, holes are formed corresponding to the portions where the conductor layers 122-1, 122-2A, 122-2B, 122-3A, and 122-3B are to be formed. In FIG. 36, a hole H12 corresponding to the conductor layer 122-1 is shown. In FIG. 37, holes H13 and H13′ corresponding to the conductor layers 122-2A and 122-2B are shown.

Furthermore, the conductor layers 122-1, 122-2A, 122-2B, 122-3A, and 122-3B are formed to be embedded in the holes H12, H13, and H13′ formed by the process described with reference to FIGS. 36 and 37.

In this manner, the semiconductor device 1 according to the second embodiment is formed.

The second embodiment also provides the same effects as those in the first embodiment.

### 4. Others

The embodiments are not limited to the above-described forms, and various modifications can be made. For example, the structure in the modification example of the first embodiment can also be applied to the second embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first wiring and a second wiring adjacent to each other in a first direction along a first face, wherein
the first wiring includes
a first extending portion extending in a second direction intersecting the first direction along the first face, and
a first plug portion extending in a third direction intersecting the first face and being in contact with the first extending portion on a first side in the third direction,
the second wiring includes
a second extending portion provided in a same layer as the first extending portion and extending in the second direction, and
a first connection portion adjacent to the first plug portion in the first direction and being in contact with the second extending portion side by side in the second direction, and
a first position of a surface of the first connection portion on a second side that is opposite to the first side in the third direction is different from a second position of a surface of the second extending portion on the second side in the third direction.

2. The semiconductor device according to claim 1, wherein, when viewed in the third direction, a width of the first plug portion in the first direction is larger than a width of the first connection portion in the first direction.

3. The semiconductor device according to claim 1, wherein the first position is located on the second side in the third direction with respect to the second position.

4. The semiconductor device according to claim 1, wherein the first position is located on the first side in the third direction with respect to the second position.

5. The semiconductor device according to claim 1, further comprising a third wiring that is in contact with the first plug portion on the second side of the first wiring in the third direction.

6. The semiconductor device according to claim 5, further comprising a first member that is in contact with the first connection portion on the second side of the second wiring in the third direction.

7. The semiconductor device according to claim 6, wherein the first member is provided on the first side in the third direction with respect to the third wiring.

8. The semiconductor device according to claim 6, wherein the first member is provided in a same layer as the third wiring.

9. The semiconductor device according to claim 8, wherein the first member is a conductor.

10. The semiconductor device according to claim 1, further comprising a substrate that is in contact with the first plug portion on the second side of the first wiring in the third direction.

11. The semiconductor device according to claim 1, wherein the second wiring is provided such that a surface of the first connection portion on the first side in the third direction is flush with a surface of the second extending portion on the first side in the third direction.

12. The semiconductor device according to claim 1, wherein
the second wiring further includes a third extending portion extending in the second direction in the same layer as the second extending portion, and
the first connection portion is sandwiched by the second extending portion and the third extending portion in the second direction and is in contact with each of the second extending portion and the third extending portion.

13. The semiconductor device according to claim 12, wherein the second wiring has a stepped shape at a point where the first connection portion and the second extending portion are connected and at a point where the first connection portion and the third extending portion are connected, when viewed in the third direction.

14. The semiconductor device according to claim 12, wherein
the first connection portion includes
a first sub-portion having the surface of the first connection portion at the first position in the third direction,
a second sub-portion sandwiched by the first sub-portion and the second extending portion in the second direction and being in contact with each of the first sub-portion and the second extending portion, and
a third sub-portion sandwiched by the first sub-portion and the third extending portion in the second direction and being in contact with each of the first sub-portion and the third extending portion, and
in a cross-section including the second direction and the third direction, the first connection portion has a stepped shape at each of a point where the first sub-portion and the second sub-portion are connected and a point where the first sub-portion and the third sub-portion are connected.

15. The semiconductor device according to claim 14, wherein each of the second sub-portion and the third sub-portion has a respective end on the second side in the third direction, a position of the respective end being located on the second side in the third direction with respect to the second position.

16. The semiconductor device according to claim 1, wherein a surface of the first connection portion on the first side in the third direction is located on the second side in the third direction with respect to a surface of the second extending portion on the first side in the third direction.

17. The semiconductor device according to claim 16, wherein
the first extending portion is provided to overlap the first plug portion when viewed in the third direction, and
the first plug portion is in contact with a surface of the first extending portion on the second side in the third direction.

18. The semiconductor device according to claim 1, wherein a center of the first plug portion and a center of the first connection portion are provided to be shifted to a first side or a second side opposite to the first side in the first direction, with respect to a center of the first extending portion and a center of the second extending portion, respectively.

19. A semiconductor device comprising:
a first wiring and a second wiring adjacent to each other in a first direction along a first face, wherein
the first wiring includes
a first extending portion extending in a second direction intersecting the first direction along the first face, and
a first plug portion extending in a third direction intersecting the first face and being in contact with the first extending portion on one side in the third direction,
the second wiring includes
a second extending portion provided in a same layer as the first extending portion and extending in the second direction, and
a first connection portion adjacent to the first plug portion in the first direction and being in contact with the second extending portion side by side in the second direction, and
the second wiring has a stepped shape at a point where the first connection portion and the second extending portion are connected when viewed in the third direction.

20. The semiconductor device according to claim 19, wherein a center of the first plug portion and a center of the first connection portion are provided to be shifted to a first side or a second side opposite to the first side in the first direction, with respect to a center of the first extending portion and a center of the second extending portion, respectively.
